(19) United States
(12) Patent Application Publication
(10) Pub. No.: US 2026/0354287 A1
(43) Pub. Date: Nov. 5, 2026

(54) SEMICONDUCTOR DEVICE AND MOUNTING STRUCTURE FOR SEMICONDUCTOR DEVICE

(71) Applicant: ROHM CO., LTD., Kyoto-shi (JP)

(72) Inventors: Ryosuke FUKUDA, Kyoto-shi (JP); Kohei TANIKAWA, Kyoto-shi (JP)

(21) Appl. No.: 19/742,704

(22) Filed: Jul. 15, 2026

Related U.S. Application Data
(63) Continuation of application No. 18/420,305, filed on Jan. 23, 2024.
Application No. 18/420,305 is a continuation of application No. PCT/JP2022/031038, filed on Aug. 17, 2022.

(30) Foreign Application Priority Data
Sep. 6, 2021 (JP) 2021-144534

(51) Int. Cl. H10W 90/00; H10W 40/22; H10W 70/65; H10W 74/10

(52) U.S. Cl. CPC H10W 90/701; H10W 40/22; H10W 70/65; H10W 74/10; H10W 90/736

(57) ABSTRACT

A semiconductor device includes a semiconductor element, a sealing resin, and a first signal terminal. The sealing resin includes a first surface facing in a thickness direction and covers the semiconductor element. The first signal terminal protrudes from the first surface and is electrically connected to the semiconductor element. The sealing resin includes a second surface facing the same side as the first surface in the thickness direction. The first surface includes a first region which is located opposite to the first signal terminal with the second surface interposed therebetween in a first direction orthogonal to the thickness direction and on which a mounting member can be disposed. The position of the second surface differs from the position of the first region in the thickness direction.

### CROSS-REFERENCE TO RELATED APPLICATIONS

This application is a Continuation application of U.S. Application Serial No. 18/420305, filed Jan. 23, 2024, which is a continuation of PCT Application No. PCT/JP2022/031038, filed Aug. 17, 2022, which claims priority to Japanese application No. 2021-144534, filed Sept. 6, 2021, all of which are incorporated herein by reference, including the original claims.

### TECHNICAL FIELD

The present disclosure relates to a semiconductor device and a mounting structure of the same.

### BACKGROUND ART

JP-A-2016-162773 discloses a semiconductor device (power module) in which a plurality of semiconductor elements are conductively bonded to a conductor layer. The semiconductor device is electrically connected to plurality of signal terminals. The signal terminals protrude relative to a sealing resin in a thickness direction.

During the use of the semiconductor device disclosed in JP-A-2016-162773, the semiconductor device is mounted on a heat sink to assure heat dissipation. A mounting member used for such mounting is typically made of a metal. The upper surface of the sealing resin is pressed against the mounting member. When the semiconductor device is downsized, the distance between the mounting member and the signal terminals becomes shorter. This may cause a decrease in the dielectric strength of the semiconductor device, and measures to address this is desired.

### BRIEF DESCRIPTION OF THE DRAWINGS

FIG. 1 is a perspective view of a semiconductor device according to a first embodiment of the present disclosure.

FIG. 2 is a perspective view corresponding to FIG. 1, from which illustration of a sealing resin is omitted.

FIG. 3 is a perspective view corresponding to FIG. 1, from which illustration of the sealing resin and a second conductive member is omitted.

FIG. 4 is a plan view of the semiconductor device shown in FIG. 1.

FIG. 5 is a plan view corresponding to FIG. 4, as seen through the sealing resin.

FIG. 6 is a partially enlarged view of FIG. 5.

FIG. 7 is a plan view corresponding to FIG. 4 as seen through a first conductive member, from which illustration of the sealing resin and the second conductive member is omitted.

FIG. 8 is a right side view of the semiconductor device shown in FIG. 1.

FIG. 9 is a bottom view of the semiconductor device shown in FIG. 1.

FIG. 10 is a sectional view taken along line X-X in FIG. 5.

FIG. 11 is a sectional view taken along line XI-XI in FIG. 5.

FIG. 12 is a partially enlarged view of the first element and its surroundings shown in FIG. 11.

FIG. 13 is a partially enlarged view of the second element and its surroundings shown in FIG. 11.

FIG. 14 is a sectional view taken along line XIV-XIV in FIG. 5.

FIG. 15 is a sectional view taken along line XV-XV in FIG. 5.

FIG. 16 is a partially enlarged view of the first signal terminal and its surroundings shown in FIG. 11.

FIG. 17 is a plan view of a mount structure of the semiconductor device shown in FIG. 1.

FIG. 18 is a front view of the mount structure shown in FIG. 17.

FIG. 19 is a plan view of a semiconductor device according to a second embodiment of the present disclosure.

FIG. 20 is a right side view of the semiconductor device shown in FIG. 19.

FIG. 21 is a front view of the semiconductor device shown in FIG. 19.

FIG. 22 is a sectional view of the semiconductor device shown in FIG. 19.

FIG. 23 is a partially enlarged view of FIG. 19.

FIG. 24 is a partially enlarged view of FIG. 22.

FIG. 25 is a plan view of a semiconductor device according to a third embodiment of the present disclosure.

FIG. 26 is a front view of the semiconductor device shown in FIG. 25.

FIG. 27 is a sectional view of the semiconductor device shown in FIG. 25.

FIG. 28 is a partially enlarged view of FIG. 27.

### DETAILED DESCRIPTION OF EMBODIMENTS

The following describes modes for carrying out the present disclosure with reference to the drawings.

### First Embodiment

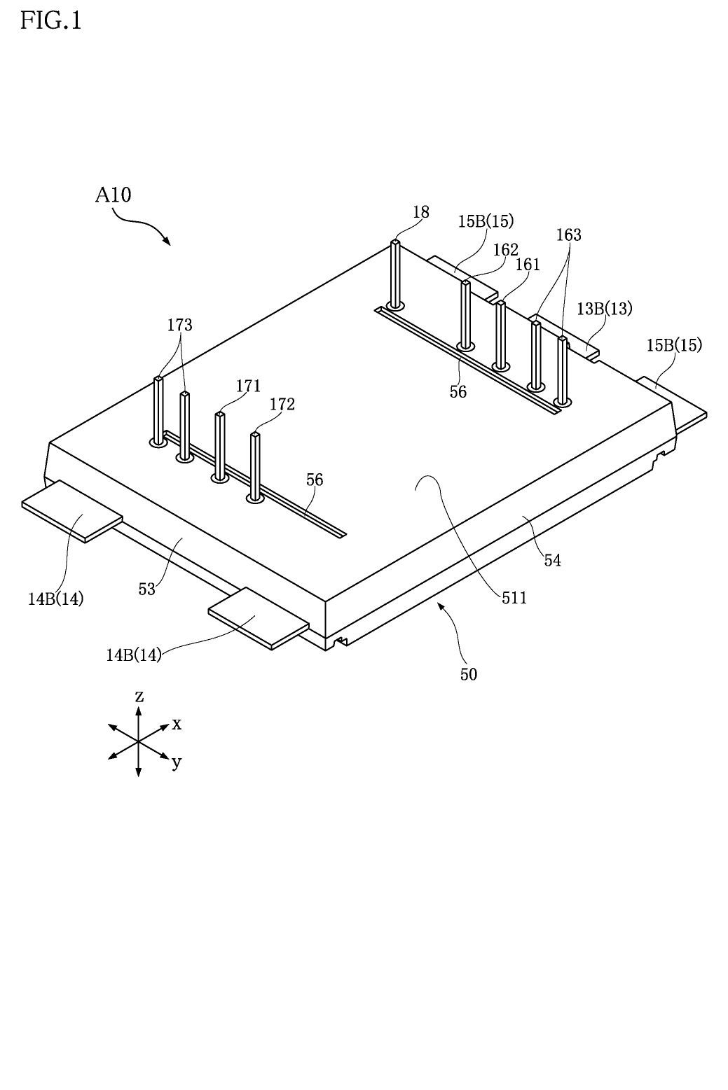

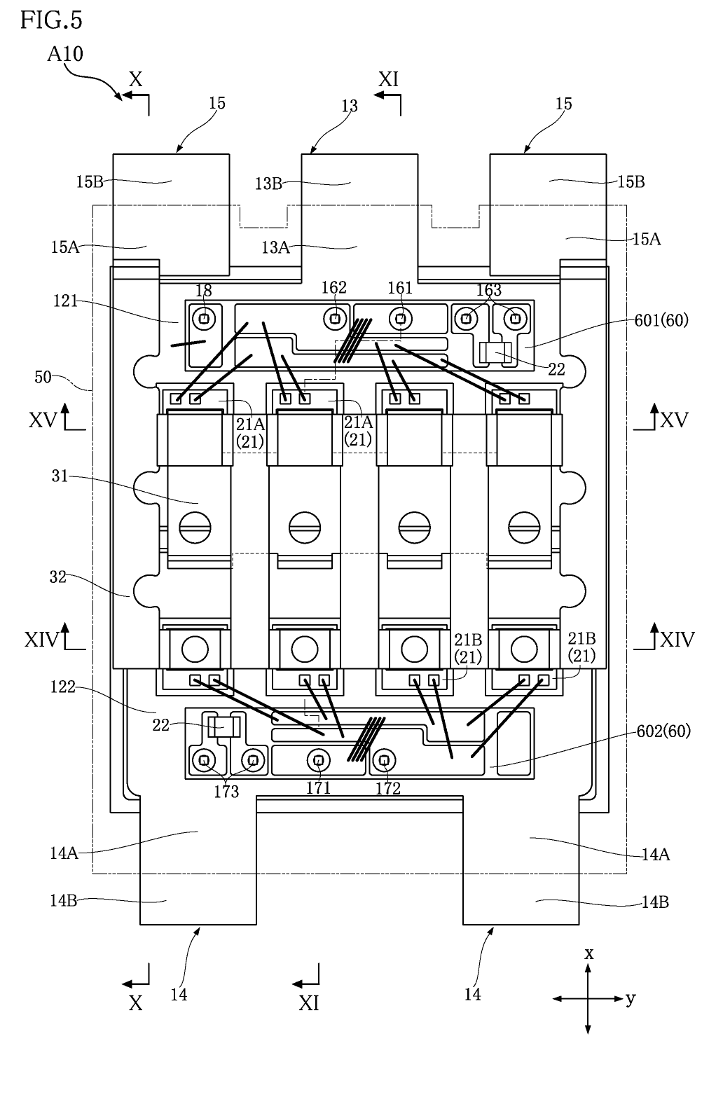

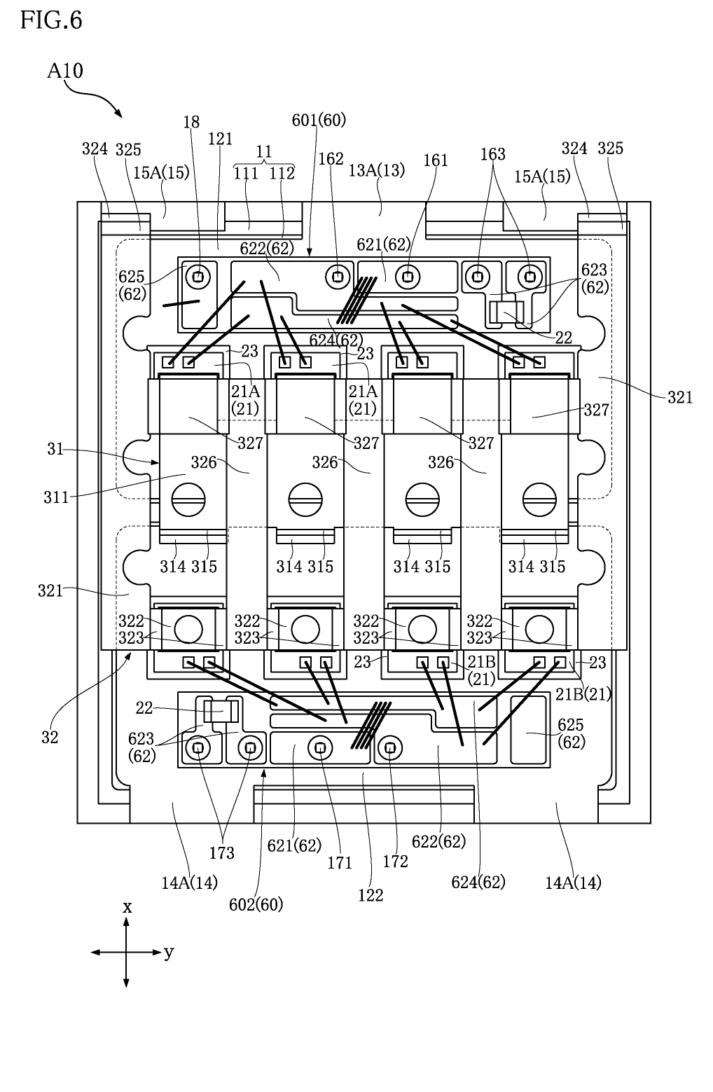

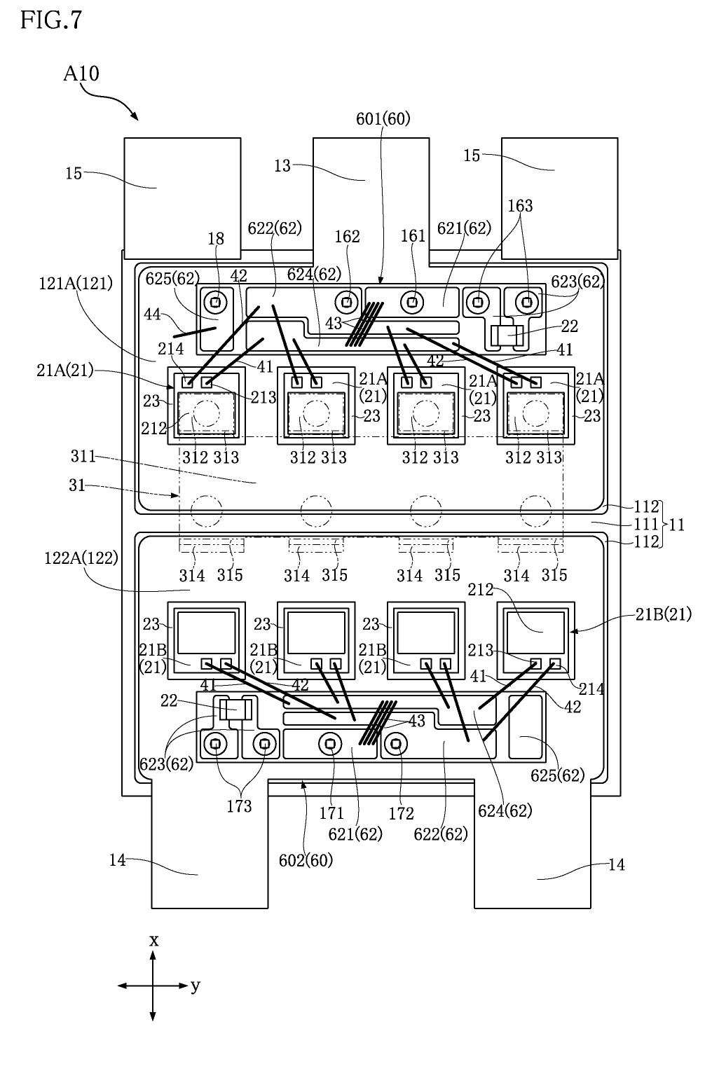

A semiconductor device A10 according to a first embodiment of the present disclosure is described below based on FIGS. 1-16. The semiconductor device A10 includes a support member 11, a first conductive layer 121, a second conductive layer 122, a first input terminal 13, an output terminal 14, a second input terminal 15, a first signal terminal 161, a fourth signal terminal 171, a plurality of semiconductor elements 21, a first conductive member 31, a second conductive member 32, and a sealing resin 50. The semiconductor device A10 further includes a second signal terminal 162, a fifth signal terminal 172, a pair of third signal terminals 163, a pair of sixth signal terminals 173, a seventh signal terminal 18, a pair of thermistors 22, and a pair of control wirings 60. The sealing resin 50 is transparent in FIGS. 5 and 6 for the convenience of understanding. The outlines of the sealing resin 50 are indicated by imaginary lines (double dashed lines) in FIG. 5. In FIG. 7, the first conductive member 31 is transparent, and illustration of the sealing resin 50 and the second conductive member 32 is omitted for the convenience of understanding. The outlines of the first conductive member 31 are indicated by imaginary lines in FIG. 7.

In the description of the semiconductor device A10, the thickness direction of the semiconductor elements 21 is referred to as a “thickness direction z”. A direction orthogonal to the thickness direction z is referred to as a “first direction x”. The direction orthogonal to the thickness direction z and the first direction x is referred to as a “second direction y”.

The semiconductor device A10 converts the DC power supply voltage applied to the first input terminal 13 and the second input terminal 15 into AC power by the semiconductor elements 21. The converted AC power is inputted through the output terminal 14 to a power supply target such as a motor. The semiconductor device A10 is used in a power conversion circuit, such as an inverter.

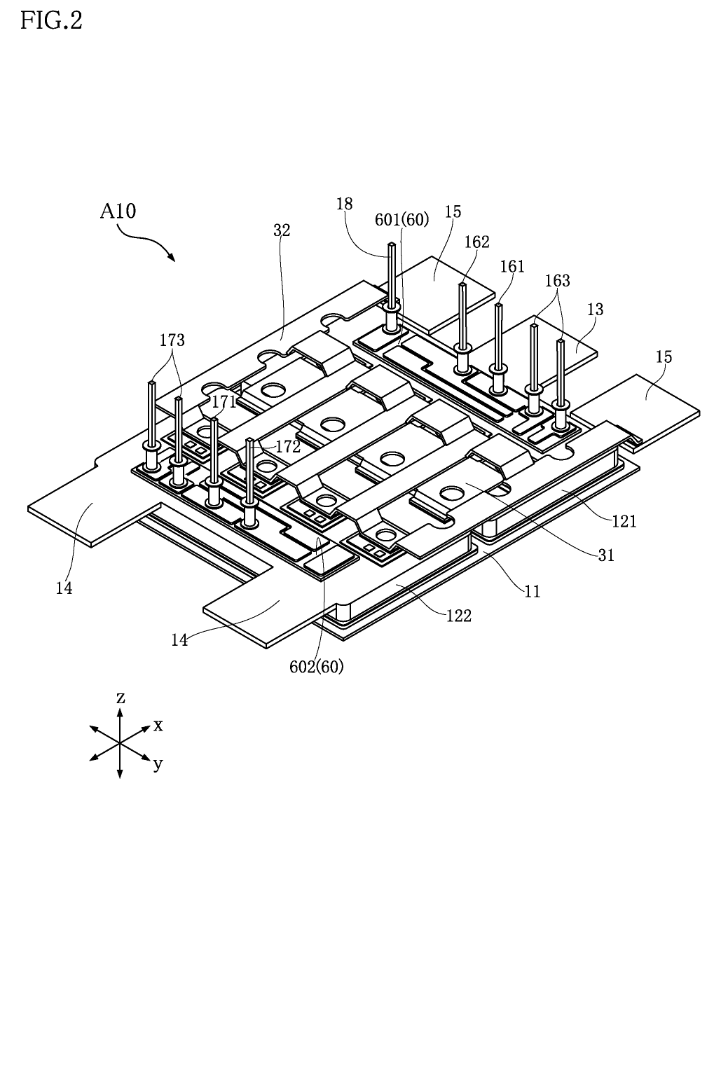

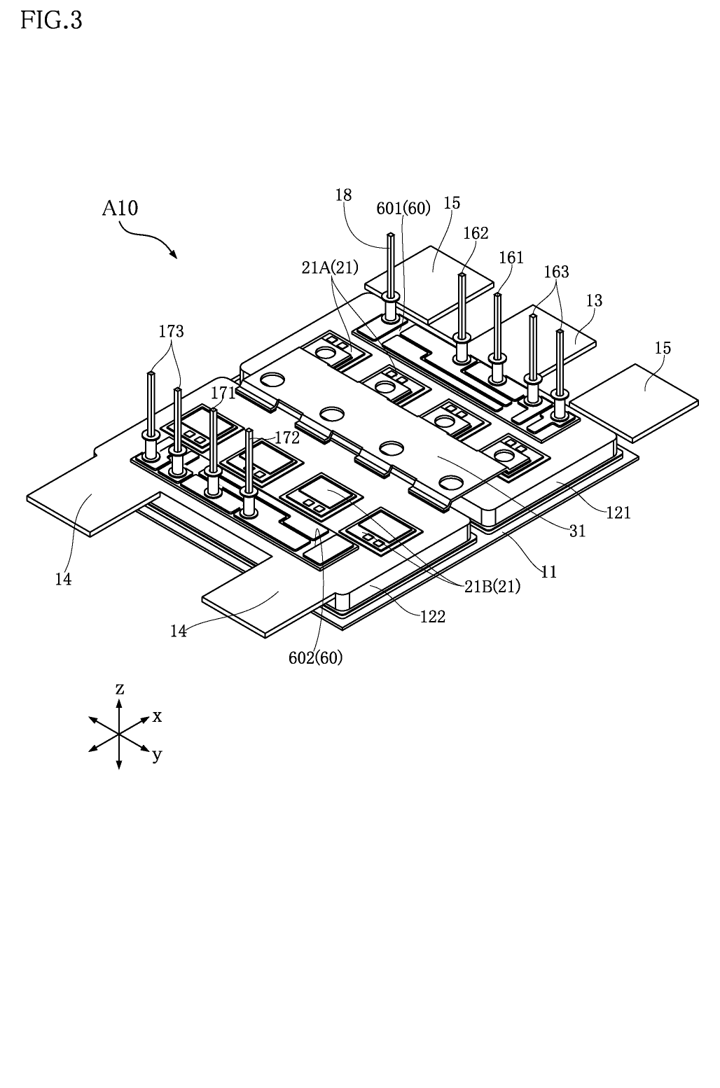

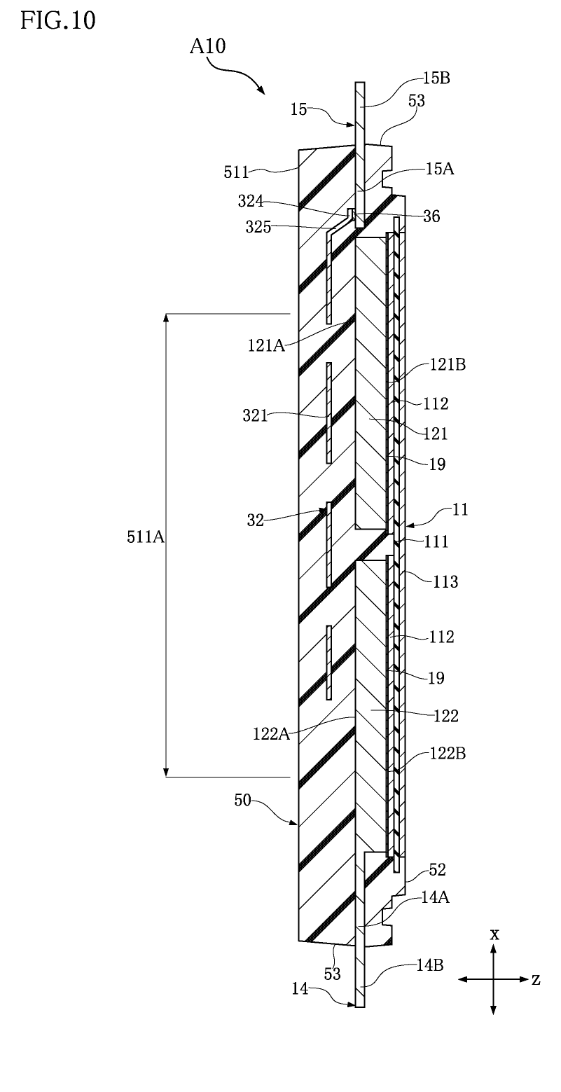

As shown in FIGS. 2 and 3, the support member 11 is located opposite to the semiconductor elements 21 with the first conductive layer 121 and the second conductive layer 122 interposed therebetween in the thickness direction z. The support member 11 supports the first conductive layer 121 and the second conductive layer 122. In the semiconductor device A10, the support member 11 is provided by a DBC (Direct Bonded Copper) substrate. As shown in FIGS. 10-15, the support member 11 includes an insulating layer 111, an intermediate layer 112, and a heat dissipation layer 113. The support member 11 is covered with the sealing resin 50 except a part of the heat dissipation layer 113.

As shown in FIGS. 10-15, the insulating layer 111 includes portions interposed between the intermediate layer 112 and the heat dissipation layer 113 in the thickness direction z. The insulating layer 111 is made of a material with relatively high thermal conductivity. The insulating layer 111 may be made of ceramic containing aluminum nitride (AlN), for example. The insulating layer 111 may be made of a sheet of insulating resin rather than ceramic. The thickness of the insulating layer 111 is smaller than the thickness of each of the first conductive layer 121 and the second conductive layer 122.

As shown in FIGS. 10-15, the intermediate layer 112 is located between the insulating layer 111 and the first and the second conductive layers 121 and 122 in the thickness direction z. The intermediate layer 112 includes a pair of regions spaced apart from each other in the first direction x. The composition of the intermediate layer 112 includes copper (Cu). As shown in FIG. 7, the intermediate layer 112 is surrounded by the periphery of the insulating layer 111 as viewed in the thickness direction z.

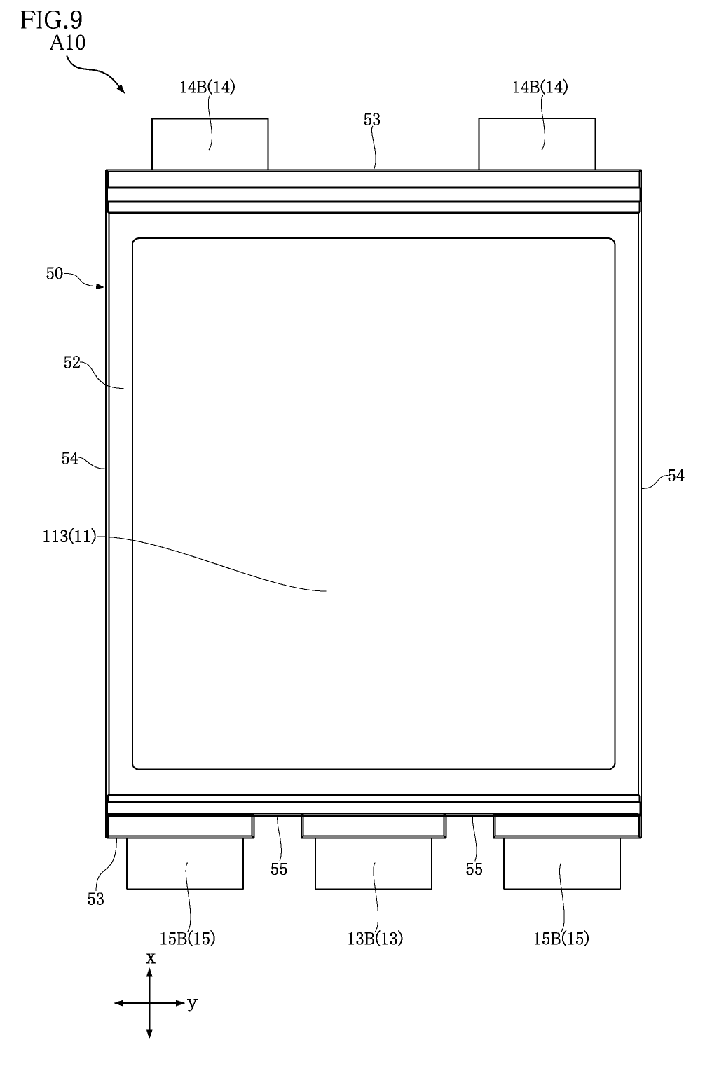

As shown in FIGS. 10-15, the heat dissipation layer 113 is located opposite to the intermediate layer 112 with the insulating layer 111 interposed therebetween in the thickness direction z. As shown in FIG. 9, the heat dissipation layer 113 is exposed from the sealing resin 50. A heat sink (not shown) is bonded to the heat dissipation layer 113. The composition of the heat dissipation layer 113 includes copper. The thickness of the heat dissipation layer 113 is larger than that of the insulating layer 111. The heat dissipation layer 113 is surrounded by the periphery of the insulating layer 111 as viewed in the thickness direction z.

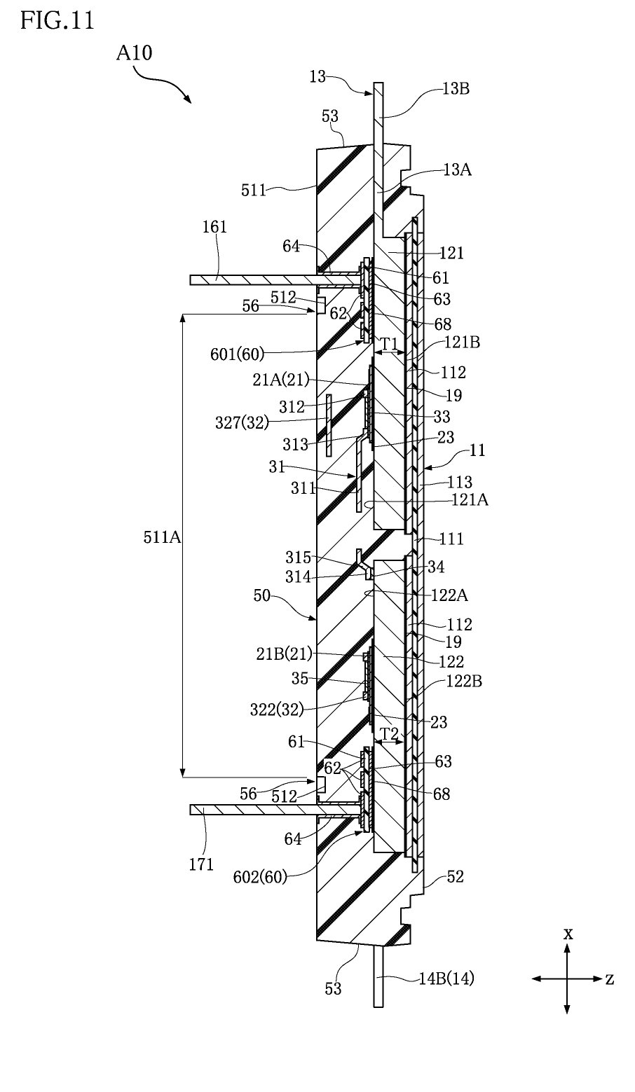

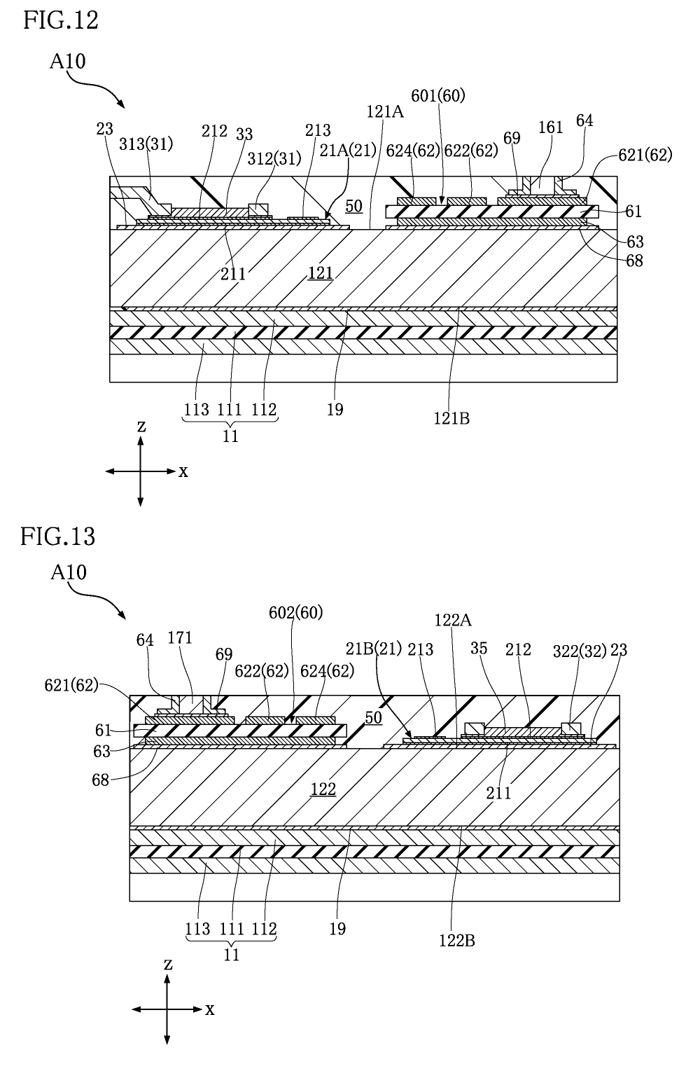

As shown in FIGS. 2 and 3, the first conductive layer 121 and the second conductive layer 122 are bonded to the support member 11. The composition of the first conductive layer 121 and the second conductive layer 122 includes copper. The first conductive layer 121 and the second conductive layer 122 are spaced apart from each other in the first direction x. As shown in FIGS. 10 and 11, the first conductive layer 121 has a first obverse surface 121A and a first reverse surface 121B facing away from each other in the thickness direction z. The first obverse surface 121A faces the semiconductor elements 21. As shown in FIG. 12, the first reverse surface 121B is bonded to one of the pair of regions of the intermediate layer 112 via a first adhesive layer 19. The first adhesive layer 19 is, for example, a brazing material containing e.g. silver (Ag) in its composition. As shown in FIGS. 10 and 11, the second conductive layer 122 has a second obverse surface 122A and a second reverse surface 122B facing away from each other in the thickness direction z. The second obverse surface 122A faces the same side as the first obverse surface 121A in the thickness direction z. As shown in FIG. 13, the second reverse surface 122B is bonded to the other one of the pair of regions of the intermediate layer 112 via the first adhesive layer 19.

As shown in FIGS. 3 and 7, each of the semiconductor elements 21 is bonded to one of the first conductive layer 121 and the second conductive layer 122. The semiconductor elements 21 are MOSFETs (Metal-Oxide-Semiconductor Field-Effect Transistor), for example. Alternatively, the semiconductor elements 21 may be switching elements, such as IGBTs (Insulated Gate Bipolar Transistor) or diodes. In the semiconductor device A10 described herein, the semiconductor elements 21 are n-channel MOSFETs of a vertical structure type. The semiconductor elements 21 include a compound semiconductor substrate. The composition of the compound semiconductor substrate includes silicon carbide (SiC).

As shown in FIG. 7, in the semiconductor device A10, the plurality of semiconductor elements 21 include a plurality of first elements 21A and a plurality of second elements 21B. The configuration of the second elements 21B is the same as that of the first elements 21A. The first elements 21A are mounted on the first obverse surface 121A of the first conductive layer 121. The first elements 21A are arranged side by side in the second direction y. The second elements 21B are mounted on the second obverse surface 122A of the second conductive layer 122. The second elements 21B are arranged side by side in the second direction y.

As shown in FIGS. 7, 12 and 13, each of the semiconductor elements 21 has a first electrode 211, a second electrode 212, a third electrode 213, and a fourth electrode 214.

As shown in FIGS. 12 and 13, the first electrode 211 faces the first conductive layer 121 or the second conductive layer 122. A current corresponding to the electric power before being converted by the semiconductor element 21 flows in the first electrode 211. That is, the first electrode 211 corresponds to the drain electrode of the semiconductor element 21.

As shown in FIGS. 12 and 13, the second electrode 212 is located opposite to first electrode 211 in the thickness direction z. A current corresponding to the electric power after being converted by the semiconductor element 21 flows in the second electrode 212. That is, the second electrode 212 corresponds to the source electrode of the semiconductor element 21.

As shown in FIGS. 12 and 13, the third electrode 213 is located on the same side as the second electrode 212 in the thickness direction z. A gate voltage for driving the semiconductor element 21 is applied to the third electrode 213. That is, the third electrode 213 corresponds to the gate electrode of the semiconductor element 21. As shown in FIG. 7, the area of the third electrode 213 is smaller than the area of the second electrode 212 as viewed in the thickness direction z.

As shown in FIG. 7, the fourth electrode 214 is located on the same side as the second electrode 212 in the thickness direction z and next to the third electrode 213 in the second direction y. The potential of the fourth electrode 214 is equal to the potential of the second electrode 212. Thus, the fourth electrode 214 is used to measure the potential of the second electrode 212, which corresponds to the source electrode.

As shown in FIGS. 12 and 13, conductive bonding layers 23 are interposed between the first conductive layer 121 or the second conductive layer 122 and the first electrodes 211 of the semiconductor elements 21. The conductive bonding layers 23 are solder, for example. Alternatively, the conductive bonding layers 23 may contain sintered metal particles. The first electrode 211 of each of the first elements 21A is conductively bonded to the first obverse surface 121A of the first conductive layer 121 via a conductive bonding layer 23. Thus, the first electrodes 211 of the first elements 21A are electrically connected to the first conductive layer 121. The first electrode 211 of each of the second elements 21B is conductively bonded to the second obverse surface 122A of the second conductive layer 122 via a conductive bonding layer 23. Thus, the first electrodes 211 of the second elements 21B are electrically connected to the second conductive layer 122.

As shown in FIGS. 5 and 11, the first input terminal 13 is located opposite to the second conductive layer 122 with the first conductive layer 121 interposed therebetween in the first direction x and is connected to the first conductive layer 121. Thus, the first input terminal 13 is electrically connected to the first electrodes 211 of the first elements 21A via the first conductive layer 121. The first input terminal 13 is a P terminal (positive electrode) to which a DC power supply voltage to be converted is applied. The first input terminal 13 extends from the first conductive layer 121 in the first direction x. The first input terminal 13 has a covered portion 13A and an exposed portion 13B. As shown in FIG. 11, the covered portion 13A is connected to the first conductive layer 121 and covered with the sealing resin 50. The covered portion 13A is flush with the first obverse surface 121A of the first conductive layer 121. The exposed portion 13B extends from the covered portion 13A in the first direction x and is exposed from the sealing resin 50. The thickness of the first input terminal 13 is smaller than that of the first conductive layer 121.

As shown in FIGS. 5 and 10, the output terminal 14 is located opposite to the first conductive layer 121 with the second conductive layer 122 interposed therebetween in the first direction x and is connected to the second conductive layer 122. Thus, the output terminal 14 is electrically connected to the first electrodes 211 of the second elements 21B via the second conductive layer 122. The AC power converted by the semiconductor elements 21 is outputted from the output terminal 14. In the semiconductor device A10, the output terminal 14 includes a pair of regions spaced apart from each other in the second direction y. Alternatively, the output terminal 14 may be a single part without a pair of regions. The output terminal 14 has a covered portion 14A and an exposed portion 14B. As shown in FIG. 10, the covered portion 14A is connected to the second conductive layer 122 and covered with the sealing resin 50. The covered portion 14A is flush with the second obverse surface 122A of the second conductive layer 122. The exposed portion 14B extends from the covered portion 14A in the first direction x and is exposed from the sealing resin 50. The thickness of the output terminal 14 is smaller than that of the second conductive layer 122.

As shown in FIGS. 5 and 10, the second input terminal 15 is located on the same side as the first input terminal 13 with respect to the first conductive layer 121 and the second conductive layer 122 in the first direction x and spaced apart from the first conductive layer 121 and the second conductive layer 122. The second input terminal 15 is electrically connected to the second electrodes 212 of the second elements 21B. The second input terminal 15 is an N terminal (negative electrode) to which a DC power supply voltage to be converted is applied. The second input terminal 15 includes a pair of regions spaced apart from each other in the second direction y. The first input terminal 13 is located between the pair of regions in the second direction y. The second input terminal 15 has a covered portion 15A and an exposed portion 15B. As shown in FIG. 10, the covered portion 15A is spaced apart from the first conductive layer 121 and covered with the sealing resin 50. The exposed portion 15B extends from the covered portion 15A in the first direction x and is exposed from the sealing resin 50.

The pair of control wirings 60 form part of conduction paths between the semiconductor elements 21 and the first signal terminal 161, the second signal terminal 162, the pair of third signal terminals 163, the fourth signal terminal 171, the fifth signal terminal 172, the pair of sixth signal terminals 173. As shown in FIGS. 5 to 7, the pair of control wirings 60 include a first wiring 601 and a second wiring 602. The first wiring 601 is located between the first elements 21A and the first and the second input terminal 13 and 15 in the first direction x. The first wiring 601 is bonded to the first obverse surface 121A of the first conductive layer 121. The first wiring 601 also forms part of the conduction path between the seventh signal terminal 18 and the first conductive layer 121. The second wiring 602 is located between the second elements 21B and the output terminal 14 in the first direction x. The second wiring 602 is bonded to the second obverse surface 122A of the second conductive layer 122. As shown in FIGS. 12 and 13, each of the pair of control wirings 60 includes an insulating layer 61, a plurality of wiring layers 62, a metal layer 63, and a plurality of sleeves 64. The control wirings 60 are covered with the sealing resin 50 except a part of each sleeve 64.

As shown in FIGS. 12 and 13, the insulating layer 61 includes portions interposed between the wiring layers 62 and the metal layer 63 in the thickness direction z. The insulating layer 61 is made of ceramic, for example. The insulating layer 61 may be made of a sheet of insulating resin rather than ceramic.

As shown in FIGS. 12 and 13, the wiring layers 62 are located on one side of the insulating layer 61 in the thickness direction z. The composition of the wiring layers 62 includes copper. As shown in FIG. 7, the wiring layers 62 include a first wiring layer 621, a second wiring layer 622, a pair of third wiring layers 623, a fourth wiring layer 624, and a fifth wiring layer 625. The pair of third wiring layers 623 are arranged next to each other in the second direction y.

As shown in FIGS. 12 and 13, the metal layer 63 is located opposite to the wiring layers 62 with the insulating layer 61 interposed therebetween in the thickness direction z. The composition of the metal layer 63 includes copper. The metal layer 63 of the first wiring 601 is bonded to the first obverse surface 121A of the first conductive layer 121 with a second adhesive layer 68. The metal layer 63 of the second wiring 602 is bonded to the second obverse surface 122A of the second conductive layer 122 with a second adhesive layer 68. The second adhesive layers 68 may be made of a material having electrical conductivity or a material that does not have electrical conductivity. The second adhesive layers 68 may be solder, for example.

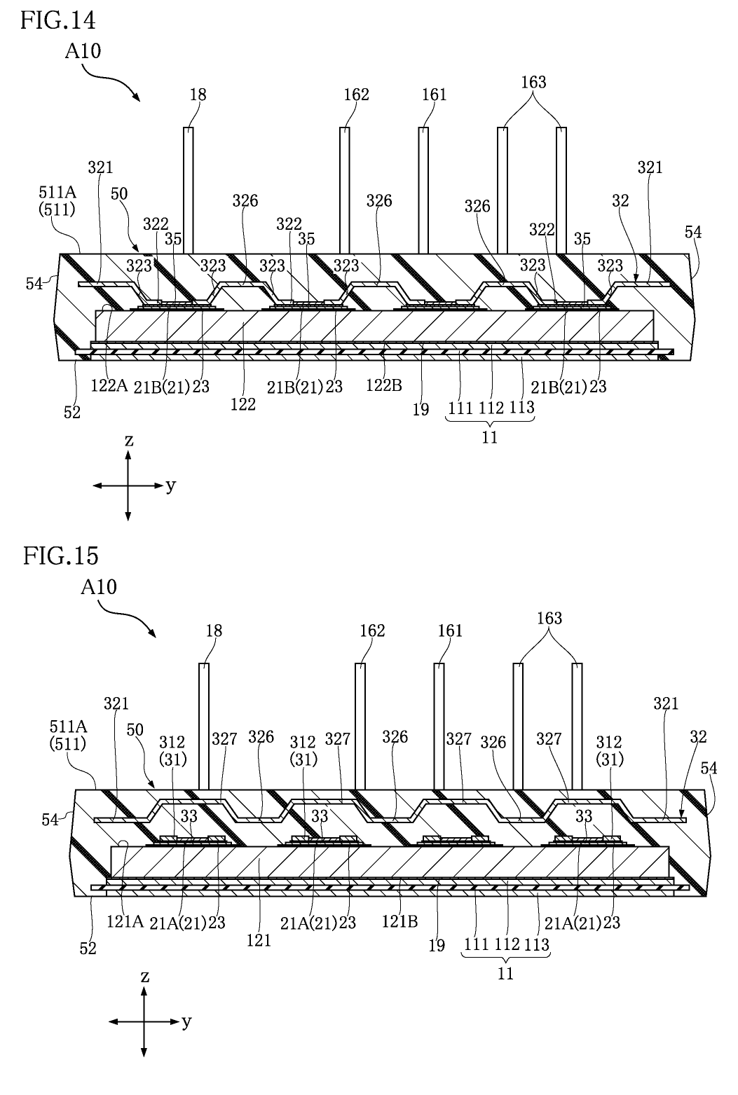

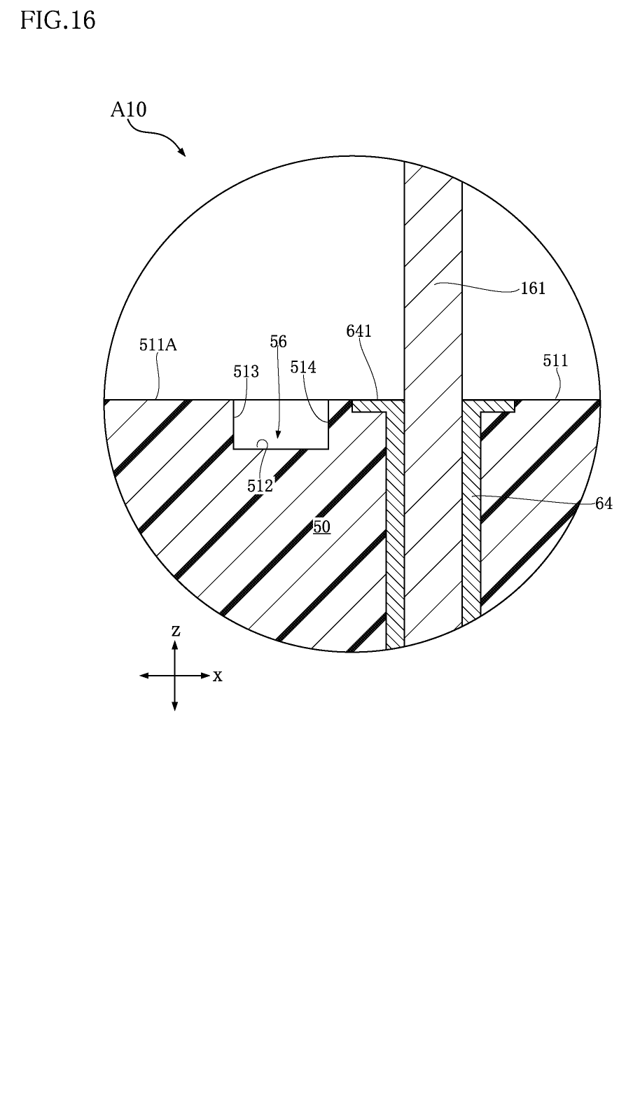

As shown in FIGS. 12 and 13, each of the sleeves 64 is bonded to one of the wiring layers 62 with a third adhesive layer 69. The sleeves 64 are made of an electrically conductive material, such as metal. Each of the sleeves 64 has a cylindrical shape extending along the thickness direction z. One end of each sleeve 64 is conductively bonded to one of the wiring layers 62. As shown in FIGS. 14 and 16, the other end of each sleeve 64 has an end surface 641 exposed at the first surface 511, described later, of the sealing resin 50. The third adhesive layers 69 have electrical conductivity. The third adhesive layers 69 may be solder, for example.

As shown in FIG. 6, one of the pair of thermistors 22 is conductively bonded to the pair of third wiring layers 623 of the first wiring 601. As shown in FIG. 6, the other one of the pair of thermistors 22 is conductively bonded to the pair of third wiring layers 623 of the second wiring 602. The thermistors 22 are NTC (Negative Temperature Coefficient) thermistors, for example. NTC thermistors have the characteristic that their resistance gradually decreases as the temperature rises. The thermistors 22 are used as a temperature detection sensor of the semiconductor device A10.

The first signal terminal 161, the second signal terminal 162, the pair of third signal terminals 163, the fourth signal terminal 171, the fifth signal terminal 172, the pair of sixth signal terminals 173 and the seventh signal terminal 18 are made of metal pins extending in the thickness direction z as shown in FIGS. 1 to 3. These terminals protrude from the first surface 511, described later, of the sealing resin 50. These terminals are individually press-fitted into the sleeves 64 of the control wirings 60. Thus, each of these terminals is supported by one of the sleeves 64 and electrically connected to one of the wiring layers 62.

As shown in FIGS. 7 and 12, the first signal terminal 161 is press-fitted into the sleeve 64 bonded to the first wiring layer 621 of the first wiring 601 of the control wirings 60. Thus, the first signal terminal 161 is supported by the sleeve 64 and electrically connected to the first wiring layer 621 of the first wiring 601. The first signal terminal 161 is also electrically connected to the third electrodes 213 of the first elements 21A. A gate voltage for driving the first elements 21A is applied to the first signal terminal 161.

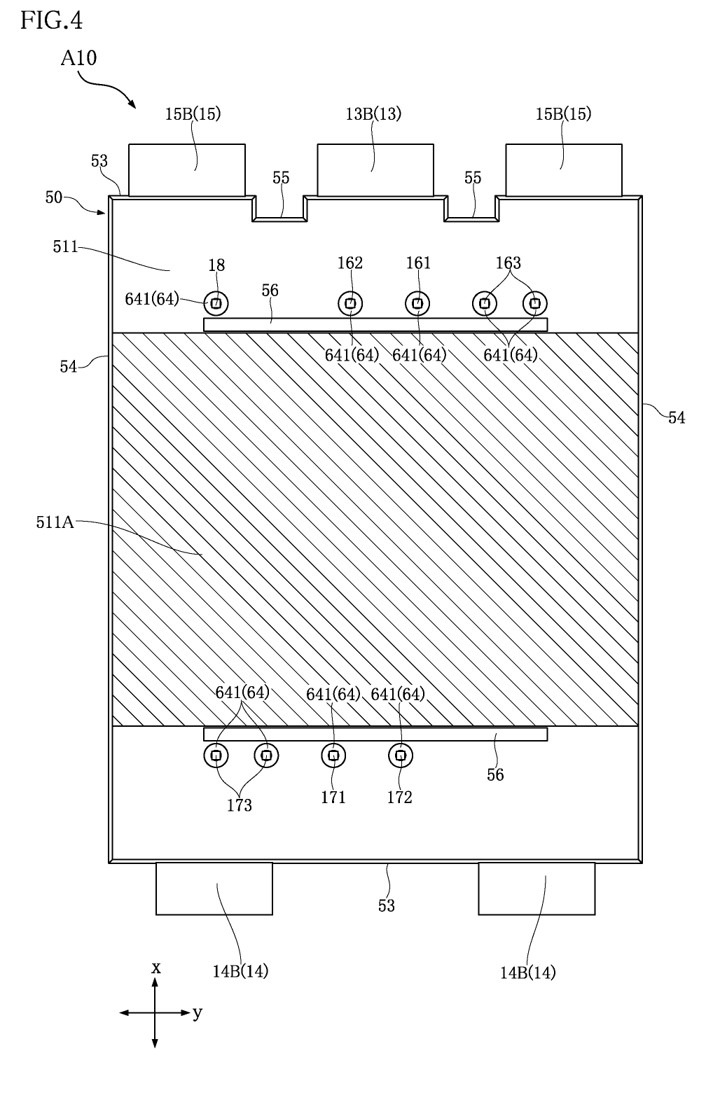

The second signal terminal 162 is located next to the first signal terminal 161 in the second direction y as shown in FIG. 4. As shown in FIG. 7, the second signal terminal 162 is press-fitted into the sleeve 64 bonded to the second wiring layer 622 of the first wiring 601 of the control wirings 60. Thus, the second signal terminal 162 is supported by the sleeve 64 and electrically connected to the second wiring layer 622 of the first wiring 601. The second signal terminal 162 is also electrically connected to the fourth electrodes 214 of the first elements 21A. To the second signal terminal 162 is applied a voltage corresponding to the current that is the highest of the currents flowing in the respective fourth electrodes 214 of the first elements 21A.

The pair of third signal terminals 163 are located opposite to the second signal terminal 162 with the first signal terminal 161 interposed therebetween in the second direction y as shown in FIG. 4. The third signal terminals 163 are arranged next to each other in the second direction y. As shown in FIG. 7, the pair of third signal terminals 163 are individually press-fitted into the pair of sleeves 64 bonded to the pair of third wiring layers 623 of the first wiring 601 of the control wirings 60. Thus, the pair of third signal terminals 163 are supported by the pair of sleeves 64 and electrically connected to the pair of third wiring layers 623 of the first wiring 601. The pair of third signal terminals 163 are also electrically connected to thermistor 22 conductively bonded to the pair of third wiring layers 623 of the first wiring 601.

As shown in FIGS. 7 an 13, the fourth signal terminal 171 is press-fitted into the sleeve 64 bonded to the first wiring layer 621 of the second wiring 602 of the control wirings 60. Thus, the fourth signal terminal 171 is supported by the sleeve 64 and electrically connected to the first wiring layer 621 of the second wiring 602. The fourth signal terminal 171 is also electrically connected to the third electrodes 213 of the second elements 21B. A gate voltage for driving the second elements 21B is applied to the fourth signal terminal 171.

The fifth signal terminal 172 is located next to the fourth signal terminal 171 in the second direction y as shown in FIG. 4. As shown in FIG. 7, the fifth signal terminal 172 is press-fitted into the sleeve 64 bonded to the second wiring layer 622 of the second wiring 602 of the control wirings 60. Thus, the fifth signal terminal 172 is supported by the sleeve 64 and electrically connected to the second wiring layer 622 of the second wiring 602. The fifth signal terminal 172 is also electrically connected to the fourth electrodes 214 of the second elements 21B. To the fifth signal terminal 172 is applied a voltage corresponding to the current that is the highest of the currents flowing in the respective fourth electrodes 214 of the second elements 21B.

The pair of sixth signal terminals 173 are located opposite to the fifth signal terminal 172 with the fourth signal terminal 171 interposed therebetween in the second direction y as shown in FIG. 4. The sixth signal terminals 173 are arranged next to each other in the second direction y. As shown in FIG. 7, the pair of sixth signal terminals 173 are individually press-fitted into the pair of sleeves 64 bonded to the pair of third wiring layers 623 of the second wiring 602 of the control wirings 60. Thus, the pair of sixth signal terminals 173 are supported by the pair of sleeves 64 and electrically connected to the pair of third wiring layers 623 of the second wiring 602. The pair of sixth signal terminals 173 are also electrically connected to thermistor 22 conductively bonded to the pair of third wiring layers 623 of the second wiring 602.

The seventh signal terminal 18 is located opposite to the first signal terminal 161 with the second signal terminal 162 interposed therebetween in the second direction y. As shown in FIG. 7, the seventh signal terminal 18 is press-fitted into the sleeve 64 bonded to the fifth wiring layer 625 of the first wiring 601 of the control wirings 60. Thus, the seventh signal terminal 18 is supported by the sleeve 64 and electrically connected to the fifth wiring layer 625 of the first wiring 601. The seventh signal terminal 18 is also electrically connected to the first conductive layer 121. A voltage corresponding to a DC power inputted to the first input terminal 13 and the second input terminal 15 is applied to the seventh signal terminal 18.

As shown in FIG. 7, first wires 41 are conductively bonded to the third electrodes 213 of the first elements 21A and the fourth wiring layer 624 of the first wiring 601. As shown in FIG. 7, third wires 43 are conductively bonded to the fourth wiring layer 624 of the first wiring 601 and the first wiring layer 621 of the first wiring 601. Thus, the first signal terminal 161 is electrically connected to the third electrodes 213 of the first elements 21A. The composition of the first wires 41 and the third wires 43 includes gold (Au). Alternatively, the composition of the first wires 41 and the third wires 43 may include copper or aluminum.

As shown in FIG. 7, first wires 41 are also conductively bonded to the third electrodes 213 of the second elements 21B and the fourth wiring layer 624 of the second wiring 602. As shown in FIG. 7, third wires 43 are also conductively bonded to the fourth wiring layer 624 of the second wiring 602 and the first wiring layer 621 of the second wiring 602. Thus, the fourth signal terminal 171 is electrically connected to the third electrodes 213 of the second elements 21B.

As shown in FIG. 7, second wires 42 are conductively bonded to the fourth electrodes 214 of the first elements 21A and the second wiring layer 622 of the first wiring 601. Thus, the second signal terminal 162 is electrically connected to the fourth electrodes 214 of the first elements 21A. As shown in FIG. 7, second wires 42 are also conductively bonded to the fourth electrodes 214 of the second elements 21B and the second wiring layer 622 of the second wiring 602. Thus, the fifth signal terminal 172 is electrically connected to the fourth electrodes 214 of the second elements 21B. The composition of the second wires 42 includes gold. Alternatively, the composition of the second wires 42 may include copper or aluminum.

As shown in FIG. 7, a fourth wire 44 is conductively bonded to the fifth wiring layer 625 of the first wiring 601 and the first obverse surface 121A of the first conductive layer 121. The seventh signal terminal 18 is thereby electrically connected to the first conductive layer 121. The composition of the fourth wire 44 includes gold. Alternatively, the composition of the fourth wire 44 may include copper or aluminum.

As shown in FIG. 7, the first conductive member 31 is conductively bonded to the second electrodes 212 of the first elements 21A and the second obverse surface 122A of the second conductive layer 122. Thus, the second electrodes 212 of the first elements 21A are electrically connected to the second conductive layer 122. The composition of the first conductive member 31 includes copper. The first conductive member 31 is a metal clip. The first conductive member 31 has a main body 311, a plurality of first bond portions 312, a plurality of first connecting portions 313, second bond portions 314, and second connecting portions 315.

The main body 311 is a main part of the first conductive member 31. As shown in FIG. 7, the main body 311 extends in the second direction y. As shown in FIG. 13, the main body 311 bridges the gap between the first conductive layer 121 and the second conductive layer 122.

As shown in FIGS. 7 and 15, the first bond portions 312 are individually bonded to the second electrodes 212 of the first elements 21A. Each of the first bond portions 312 faces the second electrode 212 of one of the first elements 21A.

As shown in FIG. 7, the first connecting portions 313 are connected to the main body 311 and the first bond portions 312. The first connecting portions 313 are spaced apart from each other in the second direction y. As shown in FIG. 12, as viewed in the second direction y, the first connecting portions 313 are inclined to become farther away from the first obverse surface 121A of the first conductive layer 121 as proceeding from the first bond portions 312 toward the main body 311.

As shown in FIGS. 7 and 12, the second bond portions 314 are bonded to the second obverse surface 122A of the second conductive layer 122. The second bond portions 314 face the second obverse surface 122A. The second bond portions 314 may extend in the second direction y. The dimension of the second bond portions 314 in the second direction y may be equal to the dimension of the main body 311 in the second direction y.

As shown in FIGS. 7 and 13, the second connecting portions 315 are connected to the main body 311 and the second bond portions 314. As viewed in the second direction y, the second connecting portions 315 are inclined to become farther away from the second obverse surface 122A of the second conductive layer 122 as proceeding from the second bond portions 314 toward the main body 311. The dimension of the second connecting portions 315 may be equal to the dimension of the main body 311 in the second direction y.

As shown in FIGS. 11, 12 and 15, the semiconductor device A10 further includes first conductive bonding layers 33. The first conductive bonding layers 33 are interposed between the second electrodes 212 of the first elements 21A and the first bond portions 312. The first conductive bonding layers 33 conductively bond the second electrodes 212 of the first elements 21A and the first bond portions 312. The first conductive bonding layers 33 may be solder, for example. Alternatively, the first conductive bonding layers 33 may contain sintered metal particles.

As shown in FIG. 11, the semiconductor device A10 further includes second conductive bonding layers 34. The second conductive bonding layers 34 are interposed between the second obverse surface 122A of the second conductive layer 122 and the second bond portions 314. The second conductive bonding layers 34 conductively bond the second obverse surface 122A and the second bond portions 314. The second conductive bonding layers 34 may be solder, for example. Alternatively, the second conductive bonding layers 34 may contain sintered metal particles.

As shown in FIG. 6, the second conductive member 32 is conductively bonded to the second electrodes 212 of the second elements 21B and the covered portion 15A of the second input terminal 15. Thus, the second electrodes 212 of the second elements 21B are electrically connected to the second input terminal 15. The composition of the second conductive member 32 includes copper. The second conductive member 32 is a metal clip. The second conductive member 32 has a pair of main bodies 321, a plurality of third bond portions 322, a plurality of third connecting portions 323, a pair of fourth bond portions 324, a pair of fourth connecting portions 325, a pair of intermediate portions 326, and a plurality of beam portions 327.

As shown in FIG. 6, the pair of main bodies 321 are spaced apart from each other in the second direction y. The main bodies 321 extend in the first direction x. As shown in FIG. 10, the main bodies 321 are disposed in parallel to the first obverse surface 121A of the first conductive layer 121 and the second obverse surface 122A of the second conductive layer 122. The main bodies 321 are located farther from the first obverse surface 121A and the second obverse surface 122A than is the main body 311 of the first conductive member 31.

As shown in FIG. 6, the intermediate portions 326 are spaced apart from each other in the second direction y and located between the pair of main bodies 321 in the second direction y. The intermediate portions 326 extend in the first direction x. The dimension of each intermediate portion 326 in the first direction x is smaller than the dimension of each main body 321 in the first direction x.

As shown in FIG. 6, the third bond portions 322 are individually bonded to the second electrodes 212 of the second elements 21B. Each of the third bond portions 322 faces the second electrode 212 of one of the second elements 21B.

As shown in FIGS. 6 and 14, the third connecting portions 323 are connected to both sides in the second direction y of each third bond portion 322. Each of the third connecting portions 323 is connected to one of the main bodies 321 and intermediate portions 326. As viewed in the first direction x, each of the third connecting portions 323 is inclined to become farther away from the second obverse surface 122A of the second conductive layer 122 as proceeding from one of the third bond portions 322 toward one of the main bodies 321 and intermediate portions 326.

As shown in FIGS. 6 and 10, the pair of fourth bond portions 324 are bonded to the covered portion 15A of the second input terminal 15. The fourth bond portions 324 face the covered portion 15A.

As shown in FIGS. 6 and 10, the pair of fourth connecting portions 325 are connected to the pair of main bodies 321 and the pair of fourth bond portions 324. As viewed in the second direction y, the fourth connecting portions 325 are inclined to become farther away from the first obverse surface 121A of the first conductive layer 121 as proceeding from the fourth bond portions 324 toward the main bodies 321.

As shown in FIGS. 6 and 15, the beam portions 327 are arranged side by side in the second direction y. As viewed in the thickness direction z, the beam portions 327 include portions individually overlapping with the first bond portions 312 of the first conductive member 31. The beam portions 327 located in the middle area in the second direction y are connected on its both sides in the second direction y to the intermediate portions 326. Each of the remaining two beam portions 327 is connected on one side in the second direction y to one of the main bodies 321 and on the other side in the second direction y to one of the intermediate portions 326. As viewed in the first direction x, the beam portions 327 protrude toward the side that the first obverse surface 121A of the first conductive layer 121 faces in the thickness direction z.

As shown in FIGS. 11, 13 and 14, the semiconductor device A10 further includes third conductive bonding layers 35. The third conductive bonding layers 35 are interposed between the second electrodes 212 of the second elements 21B and the third bond portions 322. The third conductive bonding layers 35 conductively bond the second electrodes 212 of the second elements 21B and the third bond portions 322 to each other. The third conductive bonding layers 35 may be solder, for example. Alternatively, the third conductive bonding layers 35 may contain sintered metal particles.

As shown in FIG. 10, the semiconductor device A10 further includes fourth conductive bonding layers 36. The fourth conductive bonding layers 36 are interposed between the covered portion 15A of the second input terminal 15 and the pair of fourth bond portions 324. The fourth conductive bonding layers 36 conductively bond the covered portion 15A and the fourth bond portions 324 to each other. The fourth conductive bonding layers 36 may be solder, for example. Alternatively, the fourth conductive bonding layers 36 may contain sintered metal particles.

As shown in FIGS. 10, 11, 14 and 15, the sealing resin 50 covers the first conductive layer 121, the second conductive layer 122, the semiconductor elements 21, the first conductive member 31, and the second conductive member 32. The sealing resin 50 further covers a part of each of the support member 11, the first input terminal 13, the output terminal 14 and the second input terminal 15. The sealing resin 50 has an electrically insulating property. The sealing resin 50 is made of a material containing black epoxy resin, for example. As shown in FIGS. 4 and 8 to 11, the sealing resin 50 has a first surface 511, a bottom surface 52, a pair of first side surfaces 53, a pair of second side surfaces 54, and a pair of recesses 55.

As shown in FIGS. 10 and 11, the first surface 511 faces the same side as the first obverse surface 121A of the first conductive layer 121 in the thickness direction z. As shown in FIGS. 10 and 11, the bottom surface 52 faces away from the first surface 511 in the thickness direction z. As shown in FIG. 9, the heat dissipation layer 113 of the support member 11 is exposed at the bottom surface 52.

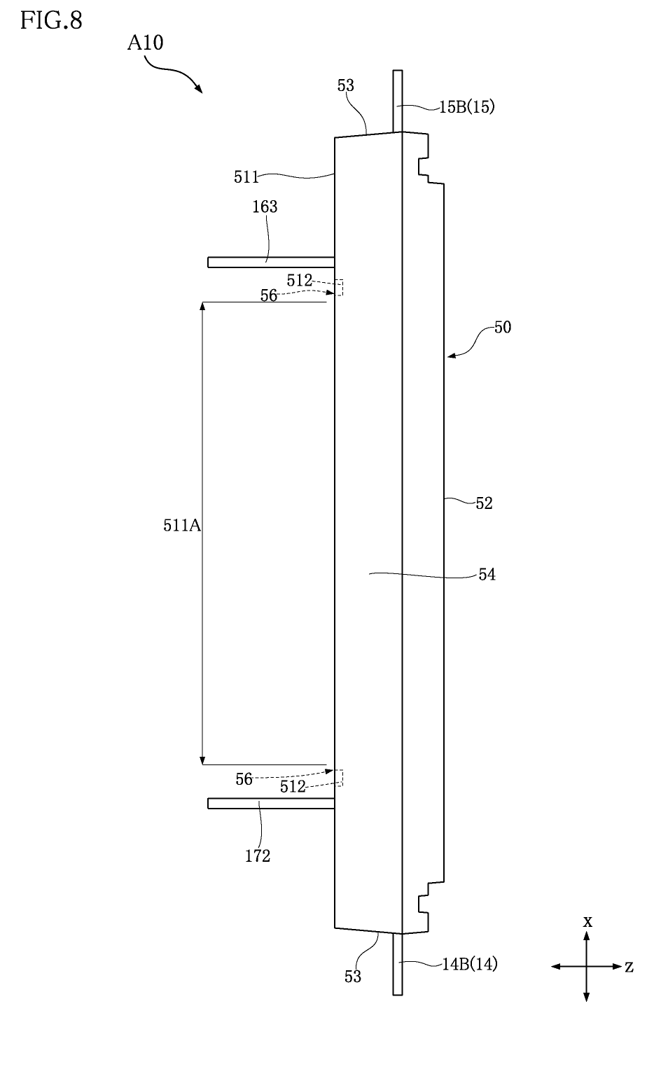

As shown in FIGS. 4 and 8, the pair of first side surfaces 53 are spaced apart from each other in the first direction x. The first side surfaces 53 face in the first direction x and extend in the second direction y. The first side surfaces 53 are connected to the first surface 511. The exposed portion 13B of the first input terminal 13 and the exposed portion 15B of the second input terminal 15 are exposed at one of the first side surfaces 53. The exposed portion 14B of the output terminal 14 is exposed at the other one of the first side surfaces 53.

As shown in FIGS. 4 and 9, the pair of second side surfaces 54 are spaced apart from each other in the second direction y. The second side surfaces 54 face away from each other in the second direction y and extend in the first direction x. The second side surfaces 54 are connected to the first surface 511 and the bottom surface 52.

As shown in FIGS. 4 and 9, the pair of recesses 55 are recessed in the first direction x from the first side surface 53 at which the exposed portion 13B of the first input terminal 13 and the exposed portion 15B of the second input terminal 15 are exposed. The recesses 55 extend from the first surface 511 to the bottom surface 52 in the thickness direction z. The recesses 55 flank the first input terminal 13 in the second direction y.

As shown in FIGS. 4 and 8, the first surface 511 of the sealing resin 50 includes a first region 511A. The first region 511A is the region where a mounting member 82, described later, can be disposed. The first region 511A is hatched in FIG. 4. As shown in FIG. 8, the sealing resin 50 has second surfaces 512. The second surfaces 512 face the same side as the first surface 511 in the thickness direction z. The first region 511A is located opposite to the first signal terminal 161 with one of the second surfaces 512 interposed therebetween in the first direction x. As shown in FIG. 16, the position of each second surface 512 in the thickness direction z differs from that of the first region 511A. As shown in FIG. 11, in the semiconductor device A10, the second surfaces 512 are located between the semiconductor elements 21 and the first region 511A in the thickness direction z.

As seen from FIG. 16, the sealing resin 50 of the semiconductor device A10 further has third surfaces 513 and fourth surfaces 514. The third surfaces 513 are located between the first region 511A and the second surfaces 512 in the thickness direction z and in the first direction x, with one of the third surfaces facing toward the first signal terminal 161 in the first direction x. One of the fourth surfaces 514 is located between a second surface 512 and the first signal terminal 161 in the first direction x. The fourth surfaces 514 face the third surfaces 513.

As shown in FIGS. 4, 11 and 16, the sealing resin 50 of the semiconductor device A10 is formed with a pair of grooves 56 recessed from the first surface 511. The grooves 56 are located opposite to each other with the first region 511A interposed therebetween in the first direction x and extend in the second direction y. Each groove 56 includes a second surface 512, a third surface 513, and a fourth surface 514. Thus, the second surfaces 512, the third surfaces 513 and the fourth surfaces 514 extend in the second direction y.

### Mount Structure B:

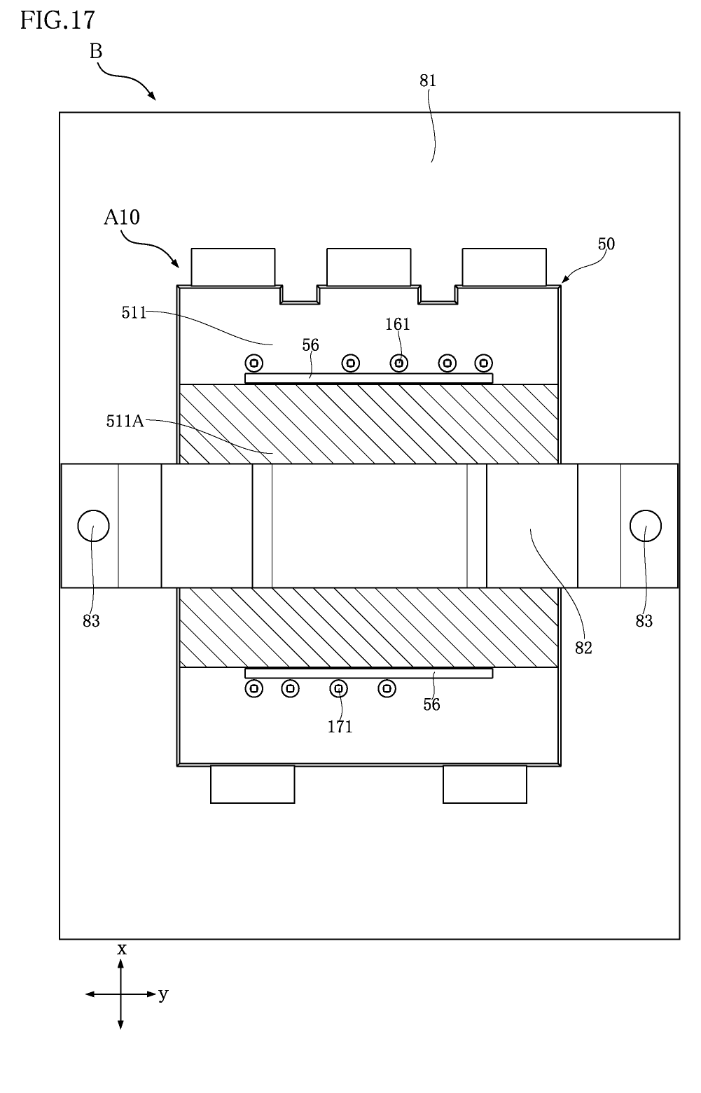

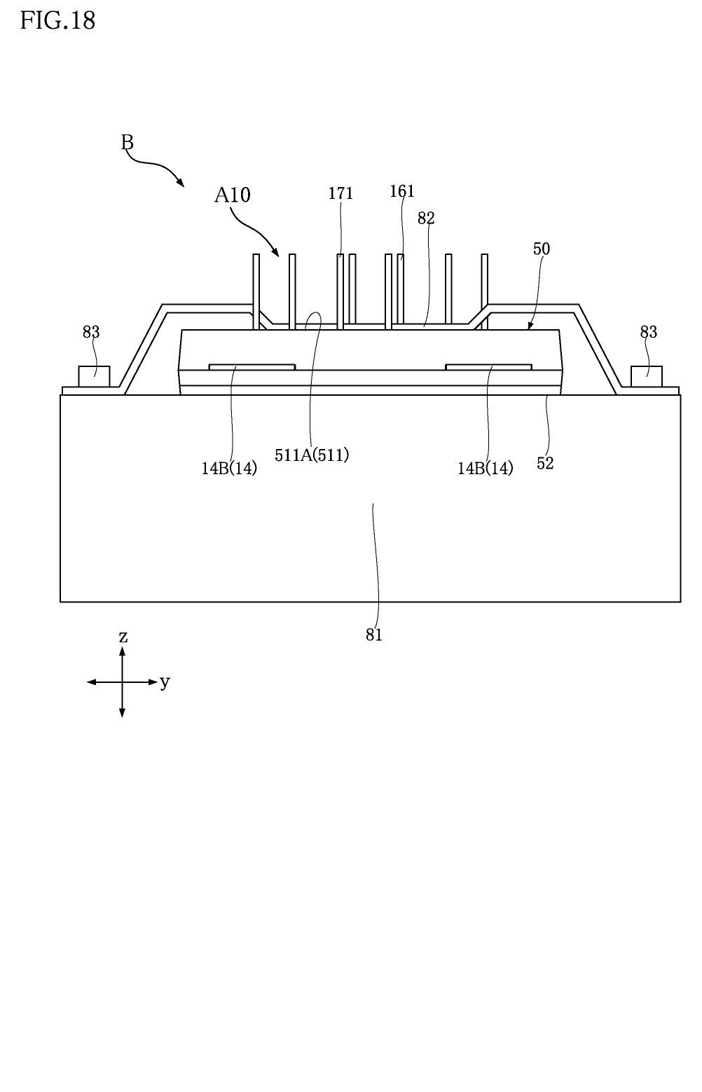

Next, a mount structure of the semiconductor device (hereinafter “mount structure B”) will be described based on FIGS. 17 and 18. The mount structure B includes the semiconductor device A10, a heat sink 81, a mounting member 82, and a plurality of fastening members 83.

As shown in FIGS. 17 and 18, the mounting member 82 is used to mount the semiconductor device A10 on the heat sink 81. The mounting member 82 is a conductor containing a metal. The mounting member 82 is a leaf spring, for example. The mounting member 82 is located between the first signal terminal 161 and the fourth signal terminal 171 in the first direction x. The fastening members 83 are used to fasten the mounting member 82 to the heat sink 81 at opposite ends of the mounting member 82. The fastening members 83 are bolts, for example.

As shown in FIG. 18, when the semiconductor device A10 is mounted on the heat sink 81 using the mounting member 82, the first region 511A of the sealing resin 50 is pressed against the mounting member 82.

Next, the effects of the semiconductor device A10 will be described.

The semiconductor device A10 includes the sealing resin 50 having the first surface 511 and the second surfaces 512 that face the same side in the thickness direction z, and the first signal terminal 161 protruding from the first surface 511 and electrically connected to the semiconductor elements 21 (the first elements 21A). The first surface 511 includes the first region 511A which is located opposite to the first signal terminal 161 with a second surface 512 interposed therebetween in the first direction x and on which the mounting member 82 can be disposed. The position of the second surfaces 512 in the thickness direction z differs from that of the first region 511A. Such a configuration increases the creepage distance of the sealing resin 50 (the distance along the surface of the sealing resin 50) from the first signal terminal 161 to the first region 511A. Thus, when the semiconductor device A10 is downsized, the reduction of the creepage distance of the sealing resin 50 from the first signal terminal 161 to the mounting member 82 is suppressed. According to the semiconductor device A10, therefore, it is possible to suppress a decrease in the dielectric strength of the semiconductor device A10 caused by the arrangement of a signal terminal and the mounting member 82 while downsizing the semiconductor device A10.

The sealing resin 50 has the third surfaces 513 facing in the first direction x and located between the semiconductor elements 21 and the first region 511A in the thickness direction z. Each third surface 513 is located between the first region 511A and a second surface 512 in the first direction x. This further increases the creepage distance of the sealing resin 50 from the first signal terminal 161 to the first region 511A, thereby more effectively suppressing a decrease in the dielectric strength of the semiconductor device A10.

The sealing resin 50 of the semiconductor device A10 has a fourth surface 514 located between a second surface 512 and the first signal terminal 161 in the first direction x. The fourth surface 514 faces a third surface 513. This further increases the creepage distance of the sealing resin 50 from the first signal terminal 161 to the first region 511A.

In the semiconductor device A10, the second surfaces 512 and the third surfaces 513 extend in the second direction y. Such a configuration increases the creepage distance of the sealing resin 50 from the second signal terminal 162, which is located next to the first signal terminal 161 in the second direction y, to the first region 511A, in addition to the creepage distance of the sealing resin 50 from the first signal terminal 161 to the first region 511A.

The semiconductor device A10 further includes the support member 11 located opposite to the semiconductor elements 21 with the first conductive layer 121 and the second conductive layer 122 interposed therebetween. The first conductive layer 121 and the second conductive layer 122 are bonded to the support member 11. The support member 11 includes the insulating layer 111, and the heat dissipation layer 113 located opposite to the first conductive layer 121 and the second conductive layer 122 with the insulating layer 111 interposed therebetween. Such a configuration allows the heat conducted from the first elements 21A and the second elements 21B to the first conductive layer 121 and the second conductive layer 122 to be efficiently dissipated outside the semiconductor device A10 while using the first conductive layer 121 and the second conductive layer 122 as conduction paths in the semiconductor device A10. In this case, when the thickness of the heat dissipation layer 113 is larger than that of the insulating layer 111, the heat conduction efficiency of the heat dissipation layer 113 in the direction orthogonal to the thickness direction z is improved, which is favorable for improving the heat dissipation of the semiconductor device A10.

The sealing resin 50 includes the pair of recesses 55 that are recessed in the first direction x from the first side surface 53 at which the first input terminal 13 and the second input terminal 15 are exposed. The recesses 55 flank the first input terminal 13 in the second direction y. Such a configuration increases the creepage distance of the sealing resin 50 between the first input terminal 13 and the second input terminal 15. This improves the dielectric strength of the semiconductor device A10.

The composition of the first conductive member 31 and the second conductive member 32 includes copper. This reduces the electrical resistance of the first conductive member 31 and the second conductive member 32 as compared with the case where the first conductive member 31 and the second conductive member 32 are wires containing aluminum in their composition. This is suitable for passing a large current in the semiconductor element 21.

### Second Embodiment:

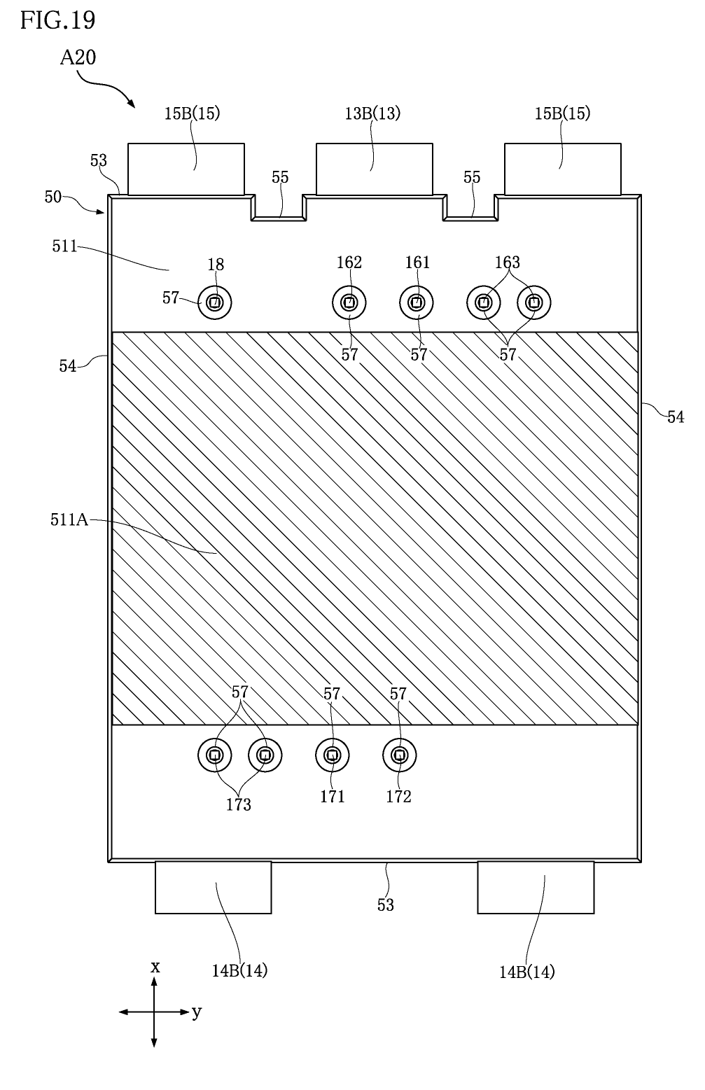

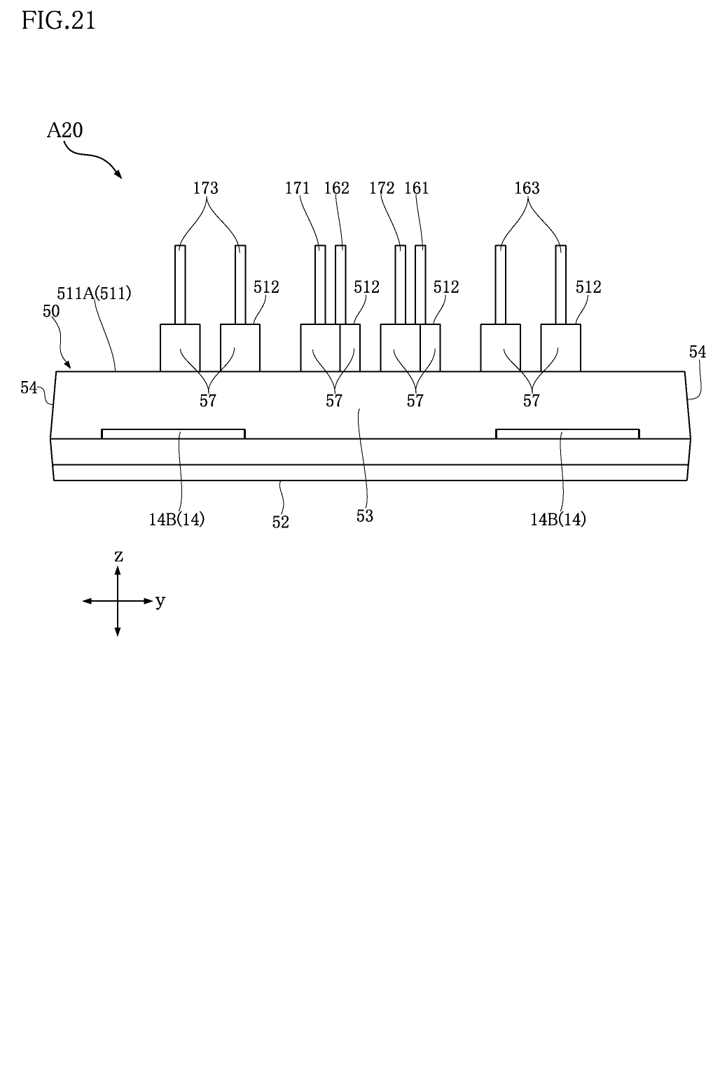

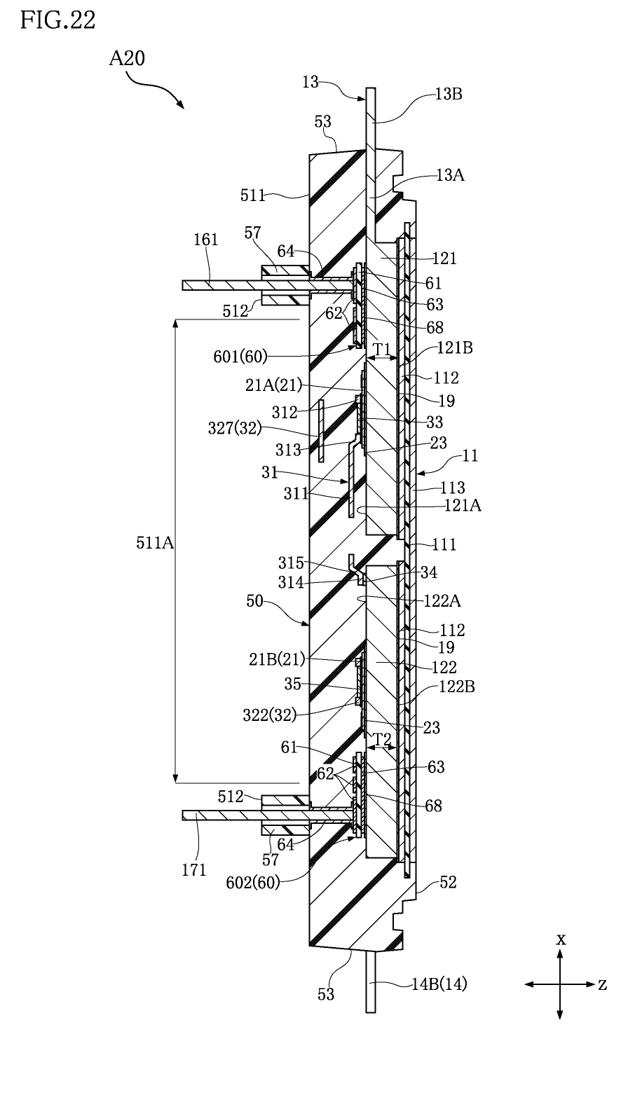

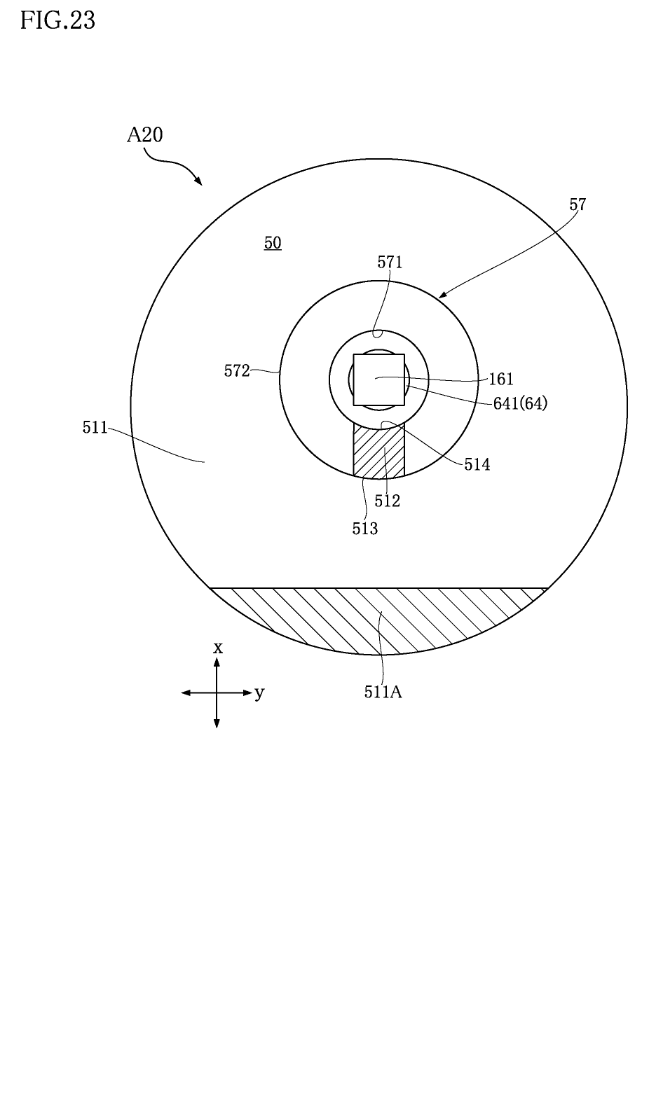

A semiconductor device A20 according to a second embodiment of the present disclosure is described below based on FIGS. 19 to 24. In the figures, the elements that are identical or similar to those of the above-described semiconductor device A10 are denoted by the same reference signs as those used for the above-described semiconductor device, and the description thereof is omitted. Note that FIG. 22 corresponds in position to FIG. 11 of the semiconductor device A10.

The semiconductor device A20 differs from the semiconductor device A10 in configuration of the sealing resin 50.

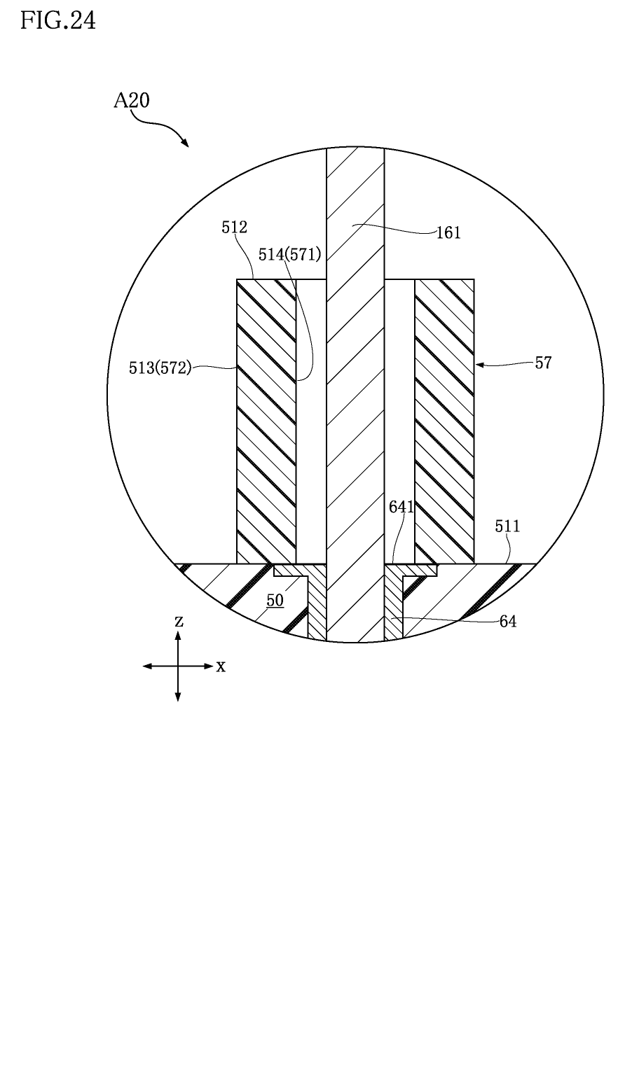

As shown in FIG. 22, the second surfaces 512 of the sealing resin 50 are located opposite to the semiconductor elements 21 with the first region 511A interposed therebetween in the thickness direction z. As shown in FIGS. 23 and 24, the third surfaces 513 of the sealing resin 50 face toward the first region 511A in the first direction x. The fourth surfaces 514 face away from the third surfaces 513 in the first direction x and are spaced apart from the signal terminals, such as the first signal terminal 161.

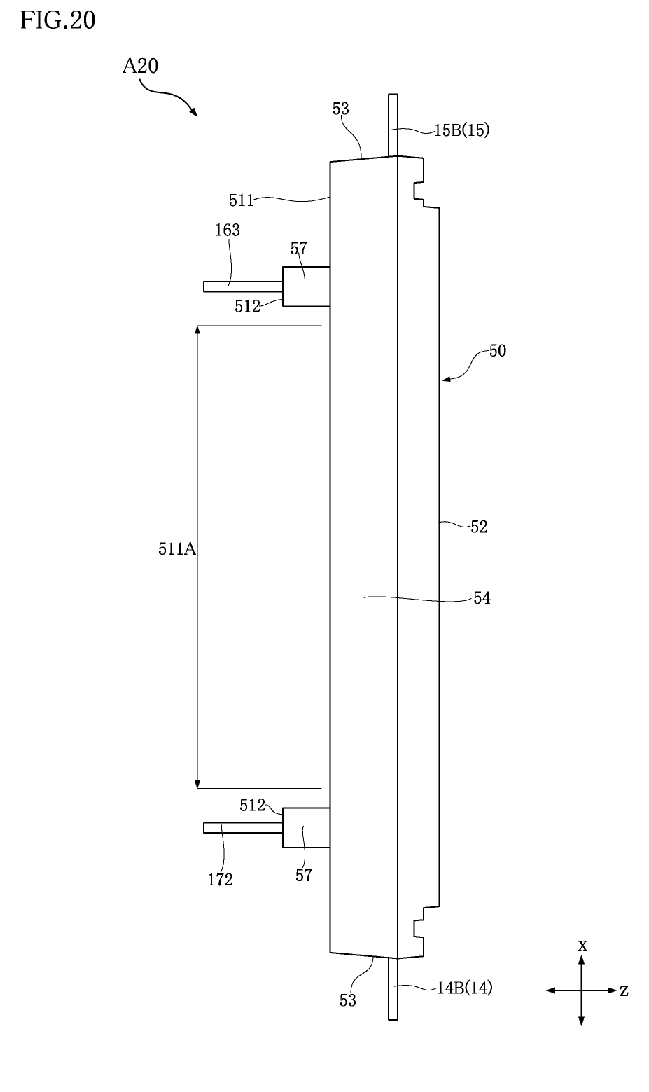

As shown in FIGS. 20 to 22, the sealing resin 50 of the semiconductor device A20 is formed with a plurality of protrusions 57 protruding from the first surface 511. Each protrusion 57 includes a second surface 512, a third surface 513, and a fourth surface 514. As shown in FIG. 19, the protrusions 57 are individually disposed at the first signal terminal 161, the second signal terminal 162, the third signal terminals 163, the fourth signal terminal 171, the fifth signal terminal 172, the sixth signal terminals 173, and the seventh signal terminal 18. As shown in FIG. 24, the protrusions 57 individually overlap with the end surfaces 641 of the sleeves 64 as viewed in the thickness direction z.

As shown in FIGS. 23 and 24, each of the protrusions 57 has an inner circumferential surface 571 and an outer circumferential surface 572. The inner circumferential surface 571 and the outer circumferential surface 572 stand on the first surface 511. One of the inner circumferential surfaces 571 surrounds the first signal terminal 161 as viewed in the thickness direction z. Each inner circumferential surface 571 includes a fourth surface 514. The space between the first signal terminal 161 and the relevant inner circumferential surface 571 is hollow. Each outer circumferential surface 572 surrounds an inner circumferential surface 571 as viewed in the thickness direction z. Each outer circumferential surface 572 includes a third surface 513. The area of the second surface 512 in the semiconductor device A20 is hatched in FIG. 23.

Next, the effects of the semiconductor device A20 will be described.

The semiconductor device A20 includes the sealing resin 50 having the first surface 511 and the second surfaces 512 that face the same side in the thickness direction z, and the first signal terminal 161 protruding from the first surface 511 and electrically connected to the semiconductor elements 21 (the first elements 21A). The first surface 511 includes the first region 511A which is located opposite to the first signal terminal 161 with a second surface 512 interposed therebetween in the first direction x and on which the mounting member 82 can be disposed. The position of the second surfaces 512 in the thickness direction z differs from that of the first region 511A. Thus, according to the semiconductor device A20 again, it is possible to suppress a decrease in the dielectric strength of the semiconductor device A20 caused by the arrangement of a signal terminal and the mounting member 82 while downsizing the semiconductor device A20. The same effect as the semiconductor device A10 is also provided owing to the configuration of the semiconductor device A20 that is in common with the semiconductor device A10.

In the semiconductor device A20, the sealing resin 50 has inner circumferential surfaces 571 each including a fourth surface 514 and outer circumferential surfaces 572 each including a third surface 513. The space between the first signal terminal 161 and the relevant inner circumferential surface 571 is hollow. This increases the dielectric strength in the area between the first signal terminal 161 and the fourth surface 514.

### Third Embodiment:

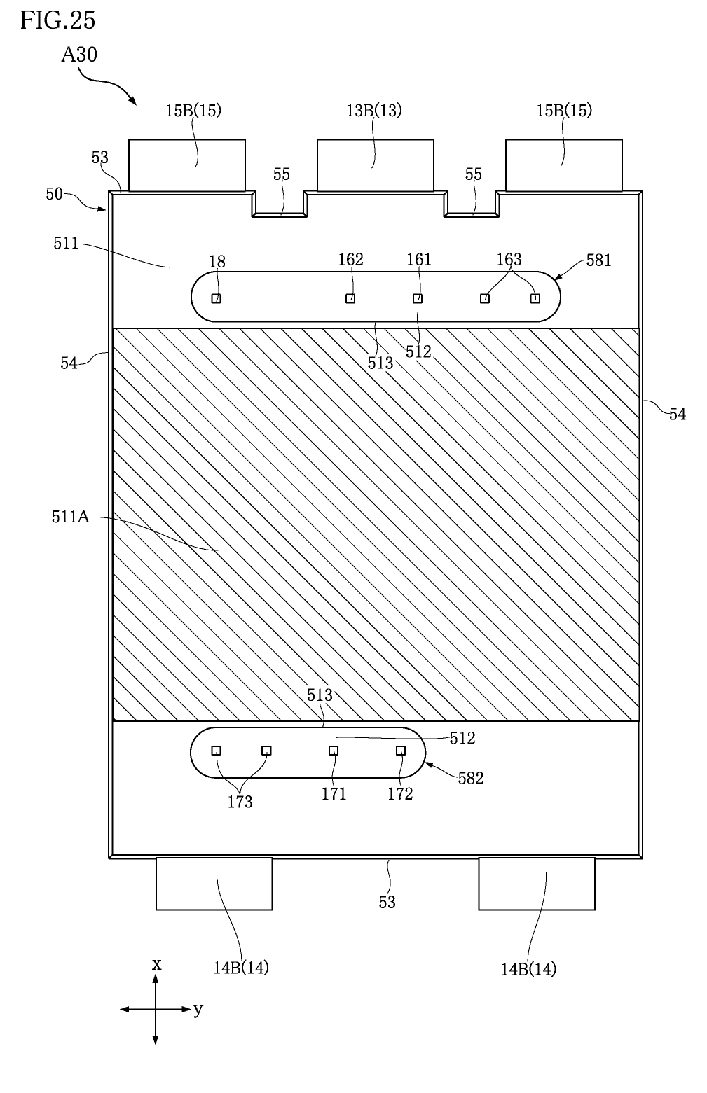

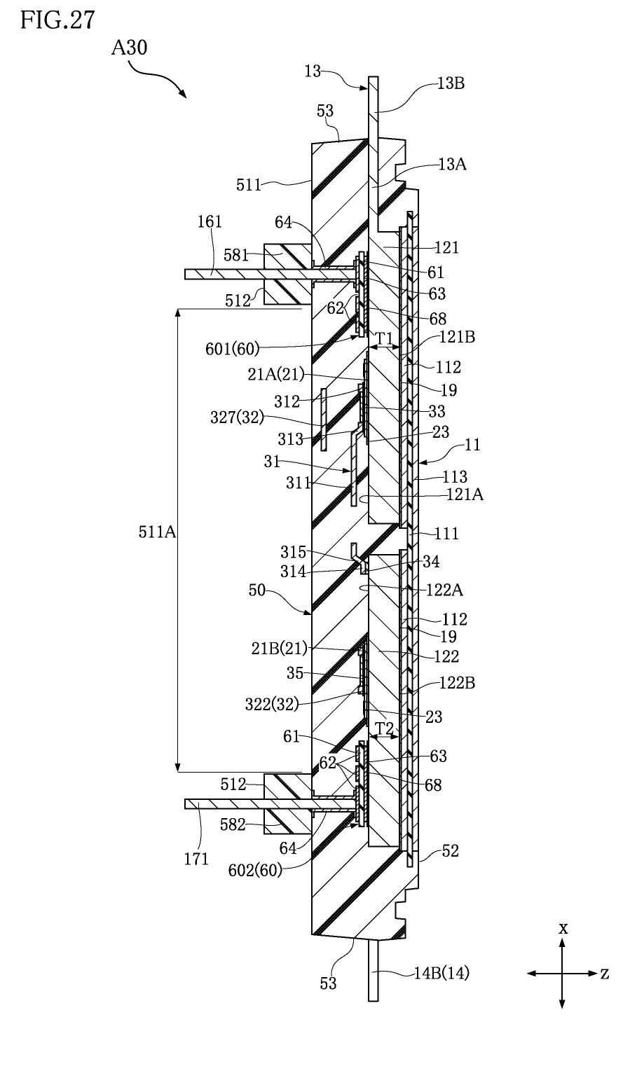

A semiconductor device A30 according to a third embodiment of the present disclosure is described below based on FIGS. 25 to 28. In the figures, the elements that are identical or similar to those of the above-described semiconductor device A10 are denoted by the same reference signs as those used for the above-described semiconductor device, and the description thereof is omitted. FIG. 27 corresponds in position to FIG. 11 of the semiconductor device A10.

The semiconductor device A30 differs from the semiconductor device A10 in configuration of the sealing resin 50.

As shown in FIG. 27, the second surfaces 512 of the sealing resin 50 are located opposite to the semiconductor elements 21 with the first region 511A interposed therebetween in the thickness direction z. As shown in FIG. 25, the third surfaces 513 of the sealing resin 50 face toward the first region 511A in the first direction x. In the semiconductor device A30, the sealing resin 50 does not have fourth surfaces 514.

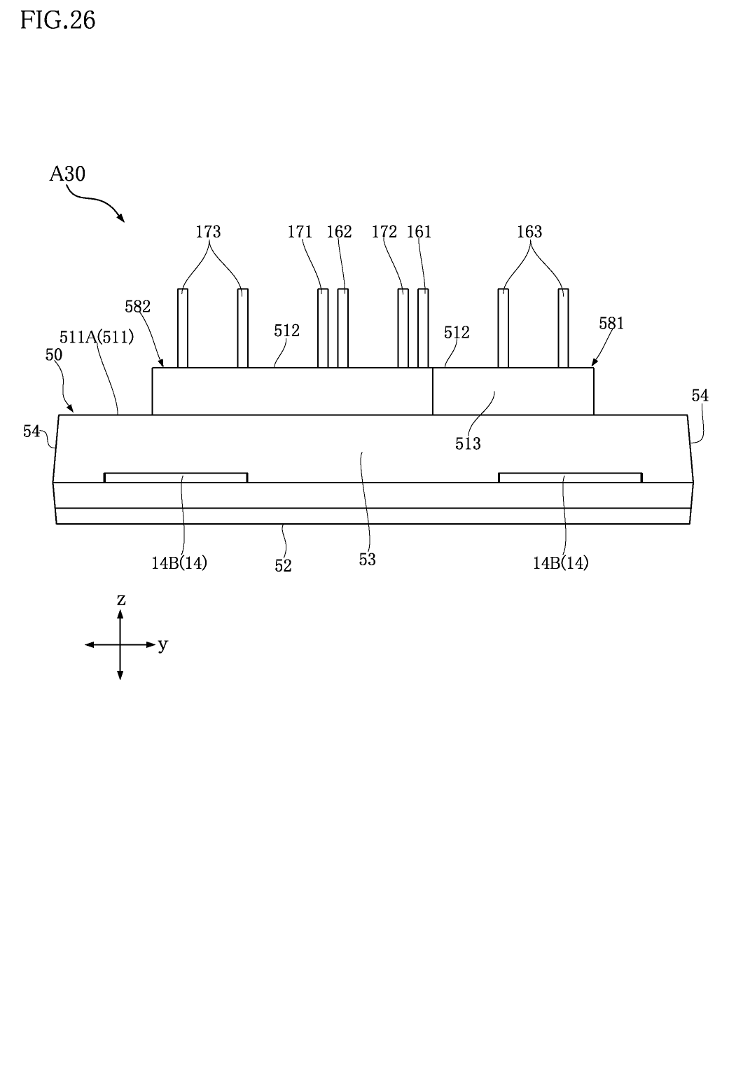

As shown in FIGS. 26 and 27, the sealing resin 50 of the semiconductor device A30 is formed with a first ridge part 581 and a second ridge part 582 protruding from the first surface 511. The first ridge part 581 and the second ridge part 582 are located opposite to each other with the first region 511A interposed therebetween in the first direction x and extend in the second direction y. Each of the first ridge part 581 and the second ridge part 582 includes a second surface 512 and a third surface 513. As shown in FIG. 25, a part of a second surface 512 is located between the first signal terminal 161 and the second signal terminal 162. As viewed in the first direction x, a third surface 513 bridges over the first signal terminal 161 and the second signal terminal 162.

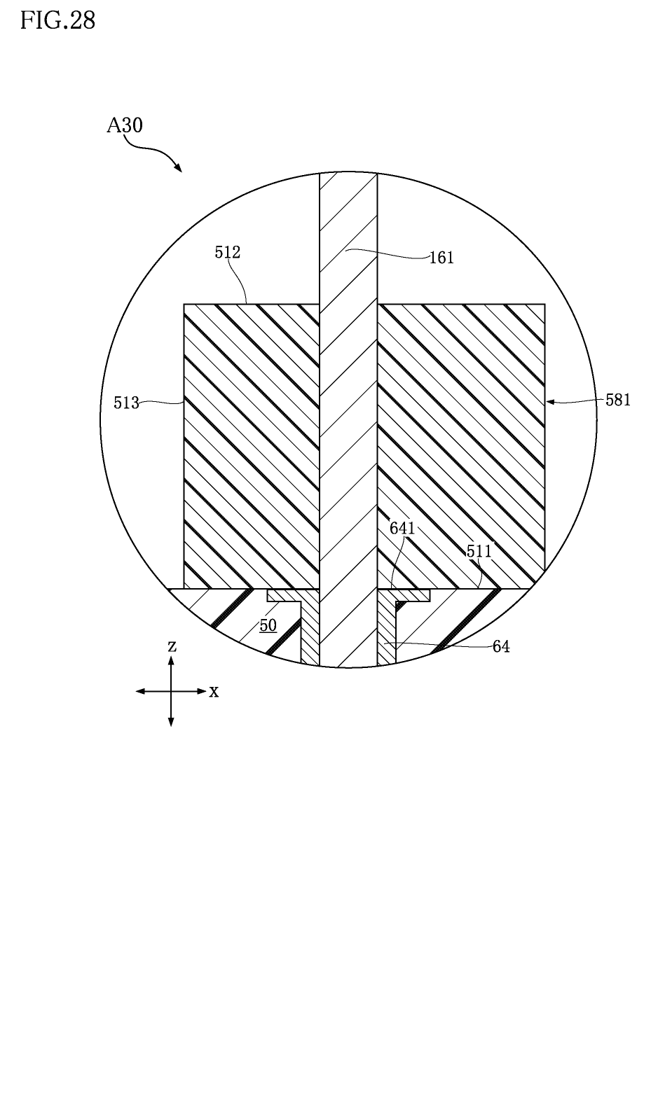

As shown in FIG. 25, the first ridge part 581 collectively surrounds the first signal terminal 161, the second signal terminal 162, the third signal terminals 163, and the seventh signal terminal 18. The second ridge part 582 collectively surrounds the fourth signal terminal 171, the fifth signal terminal 172, and the sixth signal terminals 173. As shown in FIG. 28, each of the first ridge part 581 and the second ridge part 582 covers the end surfaces 641 of relevant sleeves 64.

Next, the effects of the semiconductor device A30 will be described.

The semiconductor device A30 includes the sealing resin 50 having the first surfaces 511 and the second surfaces 512 that face the same side in the thickness direction z, and the first signal terminal 161 protruding from the first surface 511 and electrically connected to the semiconductor elements 21 (the first elements 21A). The first surface 511 includes the first region 511A which is located opposite to the first signal terminal 161 with the second surface 512 interposed therebetween in the first direction x and on which the mounting member 82 can be disposed. The position of the second surfaces 512 in the thickness direction z differs from that of the first region 511A. Thus, according to the semiconductor device A30 again, it is possible to suppress a decrease in the dielectric strength of the semiconductor device A30 caused by the arrangement of a signal terminal and the mounting member 82 while downsizing the semiconductor device A30. The same effect as the semiconductor device A10 is also provided owing to the configuration of the semiconductor device A30 that is in common with the semiconductor device A10.

In the semiconductor device A30, a third surface 513 of the sealing resin 50 bridges over the first signal terminal 161 and the second signal terminal 162 as viewed in the first direction x. This makes it possible to increase the creepage distance of the sealing resin 50 from the second signal terminal 162, which is located next to the first signal terminal 161 in the second direction y, to the first region 511A in addition to the creepage distance of the sealing resin 50 from the first signal terminal 161 to the first region 511A.

The present disclosure is not limited to the above-described embodiments. Various modifications in design may be made freely in the specific structure of each part of the present disclosure. The present disclosure includes embodiments described in the following clauses.

Clause 1.
A semiconductor device comprising:
   a semiconductor element;
   a sealing resin that includes a first surface facing in
   a thickness direction and covers the semiconductor element;
   and
      a first signal terminal protruding from the first surface and electrically connected to the semiconductor element, wherein
      the sealing resin includes a second surface facing a same
      side as the first surface in the thickness direction,
      the first surface includes a first region located
      opposite to the first signal terminal with the second surface
      interposed therebetween in a first direction orthogonal to the
      thickness direction, the first region being configured such that a mounting member is disposed thereon, and
      a position of the second surface differs from a position of the first region in the thickness direction.

Clause 2.
The semiconductor device according to clause 1, wherein
the sealing resin includes a third surface facing in the first
direction and located between the first region and the second
surface in the thickness direction, and the third surface is located between
the first region and the second surface
in the first direction.

Clause 3.
The semiconductor device according to clause 2, wherein
the second surface is located between the semiconductor
element and the first region in the thickness direction, and
the third surface faces toward the first signal terminal
in the first direction.

Clause 4. The semiconductor device according to clause 3, wherein the sealing resin includes a fourth surface located between the second surface and the first signal terminal in the first direction, and the fourth surface faces the third surface.

Clause 5. The semiconductor device according to clause 3 or 4, wherein the second surface and the third surface extend in a second direction orthogonal to the thickness direction and the first direction.

Clause 6. The semiconductor device according to clause 2, wherein the second surface is located opposite to the semiconductor element with the first region interposed therebetween in the thickness direction, and the third surface faces toward the first region in the first direction.

Clause 7. The semiconductor device according to clause 6, further comprising a second signal terminal protruding from the first surface and electrically connected to the semiconductor element, wherein the second signal terminal is located next to the first signal terminal in a second direction orthogonal to the thickness direction and the first direction, and a part of the second surface is located between the first signal terminal and the second signal terminal.

Clause 8. The semiconductor device according to clause 7, wherein the third surface bridges between the first signal terminal and the second signal terminal as viewed in the first direction.

Clause 9. The semiconductor device according to clause 6, wherein the sealing resin includes a fourth surface located between the second surface and the first signal terminal in the first direction, and the fourth surface faces away from the third surface and is spaced apart from the first signal terminal.

Clause 10. The semiconductor device according to clause 9, wherein the sealing resin includes an inner circumferential surface standing on the first surface and surrounding the first signal terminal as viewed in the thickness direction, the inner circumferential surface includes the fourth surface, and a space between the inner circumferential surface and the first signal terminal is hollow.

Clause 11. The semiconductor device according to clause 10, wherein the sealing resin includes an outer circumferential surface standing on the first surface and surrounding the inner circumferential surface as viewed in the thickness direction, and the outer circumferential surface includes the third surface.

Clause 12. The semiconductor device according to any one of clauses 1 to 11, further comprising a first conductive layer and a second conductive layer spaced apart from each other in the first direction, the semiconductor element includes a first element and a second element, the first element is conductively bonded to the first conductive layer, and the second element is conductively bonded to the second conductive layer and electrically connected to the first element.

Clause 13. The semiconductor device according to clause 12, further comprising an input terminal and an output terminal located opposite to each other with the first conductive layer and the second conductive layer interposed therebetween in the first direction, wherein the input terminal is conductively bonded to the first conductive layer, and the output terminal is conductively bonded to the second conductive layer.

Clause 14. The semiconductor device according to clause 12 or 13, further comprising a support member located opposite to the semiconductor element with the first conductive layer and the second conductive layer interposed therebetween in the thickness direction, wherein the support member includes an insulating layer, and the first conductive layer and the second conductive layer are bonded to the support member.

Clause 15. The semiconductor device according to clause 14, wherein a thickness of the insulating layer is smaller than a thickness of each of the first conductive layer and the second conductive layer.

Clause 16. The semiconductor device according to clause 15, wherein the support member includes a heat dissipation layer located opposite to the first conductive layer and the second conductive layer with the insulating layer interposed therebetween in the thickness direction, and a thickness of the heat dissipation layer is larger than a thickness of the insulating layer.

Clause 17. A mount structure of a semiconductor device, wherein the mounting member is a conductor, and when the semiconductor device as set forth in any one of clauses 1 to 16 is mounted on a heat sink using the mounting member, the mounting member is pressed against the first region.

### REFERENCE NUMERALS

A10, A20, A30: Semiconductor device B: Mount structure
11: Support member 111: Insulating layer
112: Intermediate layer 113: Heat dissipation layer
121:First conductive layer 121A: First obverse surface
121B:First reverse surface 122: Second conductive layer
122A: Second obverse surface 122B: Second reverse surface
13: First input terminal 13A: Covered portion
13B: Exposed portion 14: Output terminal
14A: Covered portion 14B: Exposed portion
15: Second input terminal 15A: Covered portion
15B: Exposed portion 161: First signal terminal
162: Second signal terminal 163: Third signal terminal
171: Fourth signal terminal 172: Fifth signal terminal
173: Sixth signal terminal 18: Seventh signal terminal
19: First adhesive layer 21: Semiconductor element
21A: First element 21B: Second element
211: First electrode 212: Second electrode
213: Third electrode 214: Fourth electrode
22: Thermistor 23: Conductive bonding layer
31: First conductive member 311: Main body
312: First bond portion 313: First connecting portion
314: Second bond portion 315: Second connecting portion
32: Second conductive member 321: Main body
322: Third bond portion 323: Third connecting portion
324: Fourth bond portion 325: Fourth connecting portion
326: Intermediate portion 327: Beam portion
33: First conductive bonding layer
34: Second conductive bonding layer
35: Third conductive bonding layer
36: Fourth conductive bonding layer
41: First wire 42: Second wire
43: Third wire 44: Fourth wire
50: Sealing resin 511: First surface
511A: First region 512: Second surface
513: Third surface 514: Fourth surface
52: Bottom surface 53: First side surface
54: Second side surface 55: Recess
56: Groove 57: Protrusion
571: Inner circumferential surface
572: Outer circumferential surface
581: First ridge part 582: Second ridge part
60: Control wiring 601: First wiring
602: Second wiring 61: Insulating layer
62: wiring layer 621: First wiring layer
622: Second wiring layer 623: Third wiring layer
624: Fourth wiring layer 625: Fifth wiring layer
63: Metal layer 64: Sleeve
641: End surface 68: Second adhesive layer
69: Third adhesive layer t: Thickness
d1, d2: Distance p1, p2, p3, p4: Spacing
z: Thickness direction x: First direction
y: Second direction

1. A semiconductor device comprising:
a semiconductor element;
a sealing resin covering the semiconductor element and having a first surface facing in a thickness direction;
a first signal terminal and a second signal terminal each protruding from the first surface in the thickness direction and electrically connected to the semiconductor element; and
a convex part protruding from the first surface and collectively covering the first signal terminal and the second signal terminal,
wherein the convex part includes a second surface facing a same side as the first surface in the thickness direction, and
a part of the second surface is located between the first signal terminal and the second signal terminal.

2. The semiconductor device according to claim 1, wherein the convex part is a ridge part extending along the first surface.

3. The semiconductor device according to claim 1, wherein the convex part includes a third surface standing from the first surface in the thickness direction, and
the third surface bridges over the first signal terminal and the second signal terminal as viewed in a direction orthogonal to the thickness direction.

4. The semiconductor device according to claim 1, wherein the first signal terminal and the second signal terminal are arranged side by side along a second direction orthogonal to a first direction, the first direction being orthogonal to the thickness direction, and
the convex part extends in the second direction.

5. The semiconductor device according to claim 4, further comprising:
at least one additional signal terminal protruding from the first surface and spaced apart from the first signal terminal and the second signal terminal in the first direction; and
a second convex part protruding from the first surface and collectively covering the at least one additional signal terminal,
wherein the convex part and the second convex part are spaced apart from each other in the first direction.

6. The semiconductor device according to claim 1, wherein each of the first signal terminal and the second signal terminal comprises a metal pin extending in the thickness direction.

7. The semiconductor device according to claim 1, wherein a position of an upper end of the convex part in the thickness direction differs from a position of an upper end of each of the first signal terminal and the second signal terminal, such that the upper end of each of the first signal terminal and the second signal terminal is exposed from the convex part.

8. The semiconductor device according to claim 1, further comprising a conductive layer having an obverse surface, wherein the semiconductor element is bonded to the obverse surface of the conductive layer.

9. The semiconductor device according to claim 8, further comprising a support member bonded to the conductive layer, wherein the support member includes an insulating layer and a heat dissipation layer located opposite to the conductive layer with respect to the insulating layer.

10. The semiconductor device according to claim 9, wherein the sealing resin covers the support member except a part of the heat dissipation layer,
the sealing resin has a bottom surface facing away from the first surface in the thickness direction, and
the heat dissipation layer is exposed at the bottom surface.

11. The semiconductor device according to claim 1, wherein the sealing resin and the convex part comprise a material having an electrically insulating property.
